(19) United States
(12) Patent Application Publication
(10) Pub. No.: US 2009/0056991 A1
(43) Pub. Date: Mar. 5, 2009

(54) Methods of Treating a Surface to Promote Binding of Molecule(s) of Interest, Coatings and Devices Formed Therefrom

(76) Inventors: Werner G. Kuhr, Denver, CO (US); Steven Z. SHI, Highlands Ranch, CO (US); Jen-Chieh WEI, Highlands Ranch, CO (US); Zhiming LIU, Englewood, CO (US); Lingyun WEI, Englewood, CO (US)

Correspondence Address: MORGAN, LEWIS & BOCKIUS, LLP., 2 PALO ALTO SQUARE, 3000 EL CAMINO REAL, PALO ALTO, CA, 94306, US

(21) Appl. No.: 12/201,974

(22) Filed: Aug. 29, 2008

Related U.S. Application Data
(60) Provisional application No. 60/969,468, filed on Aug. 31, 2007.

(51) Int. Cl. H05K 1/03; C25D 5/02; C23C 16/513; C23C 14/00; B32B 37/00; H05K 1/00

(52) U.S. Cl. 174/256; 205/118; 427/595; 205/124; 205/125; 205/122; 427/569; 204/192.1; 427/532; 156/60; 174/250

(57) ABSTRACT

The present invention generally relates to methods of treating a surface of a substrate, and to the use of the method and resulting films, coatings and devices formed therefrom in various applications including but not limited to electronics manufacturing, printed circuit board manufacturing, metal electroplating, the protection of surfaces against chemical attack, the manufacture of localized conductive coatings, the manufacture of chemical sensors, for example in the fields of chemistry and molecular biology, the manufacture of biomedical equipment, and the like. In another aspect, the present invention provides a printed circuit board, a printed circuit board, comprising: at least one metal layer; a layer of organic molecules attached to the at least one metal layer; and an epoxy layer atop said layer of organic molecules.

### RELATED APPLICATIONS

This patent application claims the benefit of, and priority to, U.S. Provisional Patent Application Ser. No. 60/969,468, filed on Aug. 31, 2007, titled “Methods of Treating a Surface to Promote Binding of Molecule(s) of Interest, Coatings and Devices Formed Therefrom,” the disclosure of which is hereby incorporated by reference in its entirety. This patent application is related to U.S. patent application Ser. No. 11/848,860, filed on Aug. 31, 2007, titled “Methods of Treating a Surface to Promote Metal Plating and Devices Formed,” the disclosure of which is hereby incorporated by reference in its entirety.

### TECHNICAL FIELD

The present invention generally relates to methods of treating a surface of a substrate, and to the use of the method and resulting films, coatings, and devices formed therefrom in variousapplications including but not limited to electronics manufacturing, printed circuit board manufacturing, metal electroplating, the protection of surfaces against chemical attack, the manufacture of localized conductive coatings, the manufacture of chemical sensors, for example in the fields of chemistry and molecular biology, the manufacture of biomedical equipment, and the like.

### BACKGROUND OF THE INVENTION

Many techniques have been described to chemically modify surfaces. The manner in which a molecule is attached onto a surface such that it retains thereon all or some of its properties is known as molecule attachment. Since the molecule of interest is usually an organic or organometallic molecule, the process generally used relies on the very large library of organic chemistry reactions mediated by specific functional groups, respectively oh the surface and on the molecule of interest, which are compatible, i.e. which can readily and if possible rapidly react, together. For example, when a surface containing hydroxyl groups —OH or amine groups —NH is available, it may be functionalized by giving the molecule of interest isocyanate, siloxane, acid chloride, etc. When the molecule of interest does not include any functional groups that are directly compatible with those of the surface, this surface may be prefunctionalized with a bifunctional intermediate organic molecule, where one of the functional groups is compatible with those of the surface, and the other with those of the molecule that it is desired to attach. From this point of view, it is found that the molecule attachment of a surface is a particular case of organic chemistry reactions, in which one of the two reagents is a surface rather than a molecule in solution.

The kinetics associated with heterogeneous reactions between a solution and a surface are substantially different from the analogous reaction in a homogeneous phase, but the reaction mechanisms are identical in principle. In certain cases, the surface is activated by pretreating it so as to create thereon functional groups with higher reactivity, so as to obtain a faster reaction. These may especially be unstable functional groups, formed transiently, for instance radicals formed by vigorous oxidation of the surface, either chemically or via irradiation. In these techniques, either the surface or the molecule of interest is modified such, that once modified, the attachment between the two species amounts to a reaction known elsewhere in the library of organic chemistry reactions.

While the vast libraries of information are helpful in identifying possible reaction candidates and/or mechanisms, much work is then required to determine if the reactions are feasible. Additionally, in many cases, such as where the surface or the molecule of interest must be modified in order to be feasible, such modification methods require relatively complex and expensive pretreatments, such as the use of vacuum installations for the plasma methods such as chemical vapor deposition (CVD), the technique of plasma assisted chemical vapor deposition (PACVD), irradiation, etc., which, moreover, do not necessarily preserve the chemical, integrity of the precursors.

These methods are genuinely operational only insofar as the surface to be treated has an electronic structure similar to that of an insulator: in the language of physicists, it may be stated that the surface needs to have localized states. In the language of chemists, it may be stated that the surface needs to contain functional groups. On metals, for example, reactive deposition treatments (CVD, PACVD, plasma, etc.) allow better attachment of the deposit to the oxide layer or at the very least to a substantially insulating segregation layer.

However, when the surface is a conductor or an undoped semiconductor, such localized states do not exist: the electronic states of the surface are delocalized states. Therefore, it is much more difficult to use the same organic chemistry reactions to attach an organic molecule of interest onto a metallic surface. Several examples do exist: these are the spontaneous chemical reactions of thiols, and of isonitriles described on metal surfaces, and especially on gold surfaces. However, these reactions cannot be exploited in all situations. Specifically, thiols, for example give rise to weak sulphur/metal bonds. These bonds are broken, for example, when the metal subsequently undergoes cathodic or anodic polarization, to form thiolates and sulphonates, respectively, which can cause molecules desorb from the surface.

The means that is currently most commonly used for attaching organic molecules onto electrically conductive or semiconductor surfaces is to circumvent the difficulty by equating it to a known problem. In many cases, it has been shown that a chemical reaction that will not proceed to any substantial extent at room temperature, can be accelerated by raising the temperature of the reaction. This has been accomplished in many cases (generally described in U.S. Pat. Nos. 6,208,553, 6,381,169, 6,657,884, 6,324,091, 6,272,038, 6,212,093, 6,451,942, 6,777,516, 6,674,121, 6,642,376, 6,728,129, US Publication Nos: 20070108438, 20060092687, 20050243597, 20060209587 20060195296 20060092687 20060081950 20050270820 20050243597 20050207208 20050185447 20050162895 20050062097 20050041494 20030169618 20030111670 20030081463 20020180446 20020154535 20020076714, 2002/0180446, 2003/0082444, 2003/0081463, 2004/0115524, 2004/0150465, 2004/0120180, 2002/010589, U.S. Ser. Nos. 10/766,304, 10/834,630, 10/628,868, 10/456,321, 10/723,315, 10/800,147, 10/795,904, 10/754,257, 60/687,464, all of which are expressly incorporated in their entirety), utilizing metallic, semi-conductor and insulating substrates. The acceleration of the kinetics of the reaction can be quite dramatic. Raising the temperature of a reaction by 100, 200 or even 400° C. can result in completion of a reaction within minutes, when it was virtually unreactive at room temperature. This allows the use of a wide variety of chemical reactions that heretofor were not available for surface molecule attachment. It also allows the molecule attachment of a large number of substrates that were previously not considered reactive. The only constraint on the process is that the reaction temperature may not exceed the temperature at which either the functionalizing molecule or the substrate itself will decompose chemically. The result is a new paradigm for the surface molecule attachment of materials that can be used in a large number of situations.

The treatment of surfaces and/or substrates is found in a wide range of applications in industries. For example, surface of devices and equipment are treated to protect against chemical attack. Medical devices are treated to provide a biocompatible coating. Considerable effort is put into the treatment of various surfaces and substrates in the microelectronic industry. Electronic components have become smaller and thinner as the desire for small, thin, and lightweight devices continues to increase. This has lead to many developments in the manufacture, design and packaging of electronic components and integrated circuits.

In one example, printed circuit boards (PCB) are widely used for packaging of integrated circuits and devices. Current PCB substrates must provide a variety of functions such as efficient signal transmission and power distribution to and from the integrated circuits, as well as provide effective dissipation of heat generated by the integrated circuits during operation. The substrates must exhibit sufficient strength to protect the integrated circuits from external forces such as mechanical and environmental stresses. As device densities increase, high density package designs such as multi-layer structures are becoming increasingly important, which present additional design challenges. Fabrication steps of PCB and semiconductor devices are costly and complicated and improvements are highly sought.

Submicron, multi-level metallization is one of the key technologies for very large scale integration (VLSI) and ultra large scale integration (ULSI) semiconductor devices. The multilevel interconnects that lie at the heart of this technology require the filling of contacts, vias, lines, and other features formed in high aspect ratio apertures. Reliable formation of these features is very important to the success of both VLSI and ULSI as well as to the continued effort to increase circuit density and quality on individual substrates and die. The patterning of very fine metal lines is a particular challenge.

As circuit densities increase, the widths of contacts, vias, lines and other features, as well as dielectric materials between them, may be decreased. Since the thickness of the dielectric materials remains invariable, the result is that the aspect ratios (i.e., their height divided by width) for most semiconductor features have to substantially increase. Many conventional deposition processes do not consistently fill semiconductor structures in which the aspect ratios exceed 6:1, and particularly when the aspect ratios exceed 10:1. As such, there is a great amount of ongoing effort being directed to the formation of void-free, nanometer-sized structures having aspect ratios of 6:1 or higher.

Electrodeposition, also referred to as electroplating or electrolytic plating, originally used in other industries, has been applied in the semiconductor industry as a deposition technique for filling small features because of its ability to grow the deposited material, such as copper, on a conductive surface and fill even high aspect ratio features substantially free of voids. Typically, a diffusion barrier layer is deposited over the surface of a feature, followed by the deposition of a conductive metal seed layer. Then, a conductive metal is electrochemically plated over the conductive metal seed layer to fill the structure/feature. Finally, the surface of the feature is planarized, such as by chemical mechanical polishing (CMP), to define a conductive interconnect feature.

Copper has become the desired metal for semiconductor device fabrication, because of its lower resistivities and significantly higher electromigration resistance as compared to aluminum and good thermal conductivity. Copper electroplating systems have been developed for semiconductor fabrication of advanced interconnect structures. Typically, copper electroplating uses a plating bath/electrolyte including positively charged copper ions in contact with a negatively charged substrate, as a source of electrons, to plate out the copper on the charged substrate.

All electroplating electrolytes have both inorganic and organic compounds at low concentrations. Typical inorganics include copper sulfate (CuSO₄), sulfuric acid (H₂SO₄), and trace amounts of chloride (Cl⁻) ions. Typical organics include accelerators, suppressors, and levelers. An accelerator is sometimes called a brightener or anti-suppressor. A suppressor may be a surfactant or wetting agent, and is sometimes called a carrier. A leveler is also called a grain refiner or an over-plate inhibitor.

Most electroplating processes generally require two processes, wherein a seed layer is first formed over the surface of features on the substrate (this process may be performed in a separate system), and then the surfaces of the features are exposed to an electrolyte solution while an electrical bias is simultaneously applied between the substrate surface (serving as a cathode) and an anode positioned within the electrolyte solution.

Conventional plating practices, include depositing a copper seed layer by physical vapor deposition (PVD), chemical vapor deposition (CVD), or atomic layer deposition (ALD) onto a diffusion barrier layer (e.g., tantalum or tantalum nitride). However, as the feature sizes become smaller, if becomes difficult to have adequate seed step coverage with PVD techniques, as discontinuous islands of copper agglomerates are often obtained in the feature side walls close to the feature bottom. When using a CVD or ALD deposition process in place of PVD to deposit a continuous sidewall layer throughout the depth of the high aspect ratio features, a thick copper layer is formed over the field. The thick copper layer on the field can cause the throat of the feature to close before the feature sidewalls are completely covered. When the deposition thickness on the field is reduced to prevent throat closure, ALD and CVD techniques are also prone to generate discontinuities in the seed layer. These discontinuities in the seed layer have been shown to cause plating defects in the layers plated over the seed layer. In addition, copper tends to oxidize readily in the atmosphere and copper oxide readily dissolves in the plating solution. To prevent complete dissolution of copper in the features, the copper seed layer is usually made relatively thick (as high as 800 A), which can inhibit the plating process from filling the features. Therefore, it is desirable to have a copper plating process that allows direct electroplating of copper on suitable barrier layer(s) without a copper seed layer.

Another challenge with direct copper plating on a suitable barrier metal layer is that the resistance of the barrier metal layer is high (low conductivity) and is known to cause high edge-plating; i.e. thicker copper plating at the edge of the substrate and no copper plating in the middle of the substrate. Also, copper tends to plate on local sites of nucleation, resulting in clusters of copper nuclei, copper clusters/crystal, so deposition is not uniform on the whole surface of the substrate. Therefore, there is a need for a copper plating process that can plate a thin copper seed layer directly on suitable barrier metals to uniformly deposit copper across the whole substrate surface and fill features before plating of a bulk copper layer.

Additionally, several approaches have been employed for connecting integrated circuits, (ICs) to printed, circuit boards. These approaches are wire, bonding, chip carriers with beam leads, and direct chip connections. Flip chip technology is one of the direct chip connection approaches. In general, a flip chip assembly forms a direct electrical connection between an electronic component and a substrate, circuit board, or carrier, by means of conductive bumps on chip bond pads of the electronic component. All of these approaches require the definition of metallic pads to be used for the generation of electrical connections between devices. Many of these connections suffer from failures due to poor adhesion between top metal layers and underling metal or insulator layers. Additionally, adhesion of PCB substrates (such as epoxy PCB substrates) onto metal layers in PCB manufacturing continues to present significant challenges to the industry. Similar issues are found in a wide variety of electronic materials, including flexible substrates, liquid crystal display (LCD) and plasma displays, solar panels, and the like.

Thus, there is a heed for additional developments and improvements in the treatment of surfaces and substrates in a wide variety of industries. It is particularly advantageous to provide methods for treating the surface of substrates that provides improved flexibility and lower costs.

### SUMMARY OF THE INVENTION

Broadly, embodiments of the present invention provide methods of treating a surface of a substrate. In one particular aspect, embodiments of the present invention provide methods of treating a surface or substrate that promote binding of one or more molecules or elements of interest to the surface.

In another aspect, embodiments of the present invention treat the surface of a substrate by thermal reaction of molecules containing reactive groups in an organic solvent or aqueous solution which deposit onto the conductive, semi-conductive and non-conductive surfaces or substrates.

According to some embodiments of the invention, films or coatings are formed on any conductive, semiconductive or non-conductive surface, by thermal reaction of molecules containing reactive groups in an organic solvent or in aqueous solution. The thermal reaction may be produced under a variety of conditions. Methods of the present invention produce organic films or coatings attached to the surface or substrate, the thickness of which is roughly equal to or greater than one molecular monolayer.

In some aspects, the present invention provides a method of treating a surface to promote binding of one or more molecules of interest to the surface, comprising the steps of: contacting the surface with an organic molecule comprising a thermally stable base bearing one or more attachment groups configured to attach the organic molecule to the surface and one or more binding groups configured to bind the organic molecule to a subsequent material of interest and; and heating the organic molecule and surface to a temperature of at least 25° C. wherein the organic molecules attach to the surface, and exhibit enhanced affinity for binding the subsequent material of interest.

In another aspect, the present invention provide a coating or film, comprising: one or more organic molecules, said organic molecule comprising a thermally stable base unit, one or more attachment groups configured to attach to a surface, and one or more binding groups. Of particular advantage, coatings or films of the present invention may be used in a large variety of applications to coat surfaces in a wide range of devices. For example, the one or more binding groups may be configured to bind to one or more biocompatible compounds to form a biocompatible coating. Alternatively, the one or more binding groups are configured to bind to one or more hydrophilic compounds to form a hydrophilic coating or conversely, a hydrophobic compound to render the surface more hydrophobic. In some embodiments, the one or more binding groups are configured to bind to one or more corrosive resistant compounds to form a corrosive resistant coating. In additional embodiments; the one or more binding groups are configured to bind to one or more compounds exhibiting optical absorption properties. In further aspects, the one or more binding groups may be configured to bind to one or more compounds exhibiting negative refractive index to form a stealth coating. In yet another aspect, the coating or film comprises attachment and binding groups each configured to bind with a separate surface such that the coating is sandwiched between two substrates forming, a structure. In some embodiments the structure may be used as a liquid crystal display (LCD), or a plasma display. Additionally, the structure is used as a flexible substrate. Further, the structure may be used as a solar panel.

In another aspect, embodiments of the present invention provide for additional cleaning, baking, etching, chemical oxidation or other pre-treatment of the surface prior to the deposition or attachment of the molecule to enhance the deposition of the molecule, the reaction of the molecule to the surface, or the ability of the surface to bond with the molecules as deposited.

In other aspects, embodiments of the present invention provide structures or films of organic molecular layers that promote favorable deposition or attachment of metal elements or molecules on surfaces which may be advantageously employed in many processes.

In further aspects, a printed circuit board is provided comprising a polymer material, such as an epoxy, which may contain a substantial amount of a filler material, such as glass, silica, or other materials, modified on its surface with a chemical adhesive material, such as a porphyrin, that substantially alters its chemical affinity for a metal, such as but not limited to copper, in order to facilitate strong adhesion between the polymer composite and the metal layer. A second layer of the chemical adhesive layer may be applied, to the metal surface, to promote adhesion between it and subsequent polymer (epoxy/glass) layers. In some embodiments, the PCB is a multilayer conductive structure.

For example in one aspect, a printed circuit board is provided, comprising: at least one metal layer; a layer of organic molecules attached to the at least one metal layer; and an epoxy layer atop said layer of organic molecules. In some embodiments the at least one metal layer exhibits a peel strength of greater than 0.5 kg/cm and a surface roughness of less than 250 nm. In some embodiments, the at least one metal layer further comprises patterned metal lines formed thereon, wherein the patterned metals lines having a width of equal to and less than 25 microns. Additionally, patterned metal lines may have a width of equal to and less than 15 microns, 10 microns or 5 microns.

In another aspect of the present invention, a printed circuit board is provided having one or more metal layers and one or more epoxy layers formed thereon, characterized in that at least one of said one or more metal layers exhibits a peel strength of greater than 0.5 kg/cm and a surface roughness of less than 250 nm.

In yet another aspect of the present invention, a printed circuit board is provided having one or more metal layers and one or more epoxy layers, characterized in that at least one of said one or more metal layers further comprises patterned metal lines formed thereon, said patterned metals lines having a width of 25 microns and less.

Of further advantage, embodiments of the present invention provide methods of treating a surface by selectively depositing materials on a surface or substrate by selectively contacting molecules on the surface to form regions, or patterned regions, which are then processed to form selective areas of desired molecules or components thereon, such as but not limited to metals or semiconductors. In this case, the adhesive molecular layer is either contacted to specific regions of the substrate, using photoresist and optical lithography, as is conventionally used in the art, or it is applied to the entire surface and selectively activated. This can be accomplished by photoactivation through a lithographic process, ion beam activation or any other technique that can provide adequate spatial imaging of a surface.

Additionally, embodiments of the present invention provide methods of forming ordered molecule assemblies on a surface or substrate which is subsequently processed, for example by plating with a metal element, such as copper and the like.

Embodiments of the present invention further provide kits comprising one or more heat resistant organic molecules derivatized with one or more attachment groups and instruction materials for carrying out a process of treating a surface to promote binding of one or more molecules of interest to the surface or substrate.

The fabrication of high density semiconductor devices can benefit from the use of this monolayer as a precursor for the deposition of a metal layer onto a substrate. Particularly, the invention relates to methods and systems for electrochemical deposition of a metal layer on a semiconductor substrate.

### BRIEF DESCRIPTION OF THE FIGURES

The foregoing and other aspects of the present invention will be apparent upon consideration of the following detailed description, taken in conjunction with the accompanying drawings, in which like reference characters refer to like parts throughout, and in which:

FIG. 1A depicts an exemplary reaction scheme for attaching organic molecules or films to the surface of a substrate according to one embodiment of the present invention;

FIG. 1B illustrates experimental process flow diagrams illustrating one embodiment of the method of the present invention;

FIG. 2 depicts a simplified schematic diagram of a molecular interface and device formed according to one embodiment of the present invention;

FIG. 3 depicts exemplary embodiments of organic molecules with various X and Y groups suitable for attachment to metal, semiconductor, and organic substrates, respectively, according to embodiments of the present invention;

FIG. 4 illustrates the attachment of a thiol-linker molecule 16 on the surface of a metal substrate, such as but not limited to copper substrate, as evidenced by Cyclic Voltammetry according to one embodiment of the present invention;

FIG. 5 illustrates the attachment of a hydroxy-linker molecule 1006 on surfaces of semiconductor substrates, such as but not limited to (a) Si, (b) TiN, (c) TiW, and (d) WN, as evidenced by Cyclic Voltammetry according to one embodiment of the present invention;

FIG. 6; illustrates the attachment of a hydroxy-linker molecule 258 on surfaces of semiconductor barrier substrates, such as but not limited to Ta and TaN, as evidenced by Laser Desorption Time-of-Flight Mass Spectroscopy according to one embodiment of the present invention;

FIG. 7 illustrates, the attachment of a hydroxy-linker molecule 258 on a surface of an organic substrate, such as but not limited to a PCB epoxy substrate, as evidenced by Laser Desorption Time-of-Flight Mass Spectroscopy according to one embodiment of the present invention;

FIG. 8 illustrates the attachment of a ammo-linker molecule 1076 on a surface of an organic substrate, such as but not limited to a PCB epoxy substrate, as evidenced by Fluorescence Spectroscopy according to one embodiment of the present invention;

FIG. 9 illustrates the robustness of molecule layer attached on a semiconductor substrate: no degradation after exposure to an electrolytic plating solution, as characterized by Cyclic Voltammetry according to one embodiment of the present invention;

FIG. 10 illustrates the robustness of molecule layer attached on a PCB epoxy substrate: no degradation after copper plating and peeling, as characterized by UV absorption (reflectance mode) according to one embodiment of the present invention;

FIG. 11 shows photographs of test coupons demonstrating the enhancement of copper electroplating and adhesion by porphyrin molecules formed on a semiconductor substrate according to one embodiment of the present invention;

FIG. 12 shows photographs of test coupons demonstrating the enhancement of copper electroless plating, and adhesion by porphyrin molecules formed on a PCB epoxy substrate according to one embodiment of the present invention;

FIG. 13 is an example of a test sample layout used to conduct peel strength tests for epoxy lamination on copper;

FIG. 14 are simplified cross sectional views showing the preparation of test samples and illustrating the lamination process used; and

FIG. 15 illustrates peel strength and surface roughness for devices according to the present invention as compared to control substrates

### DESCRIPTION OF THE INVENTION

It is to be understood that both the foregoing general description and the following description are exemplary and explanatory only and are not restrictive of the methods and devices, described herein. In this application, the use of the singular includes the plural unless specifically state otherwise. Also, the use of “or” means “and/or” unless state otherwise. Similarly, “comprise,” “comprises,” “comprising,” “include,” “includes” “including” “has” and “having” are not intended to be limiting.

In one aspect, the present invention provides a process for attaching, depositing and/or growing; a film of an organic molecular layer on(to) a variety of surfaces, which provides a solution to the abovementioned problems of the prior art.

According to some embodiments of the invention, films are formed on any conductive, semiconductive or non-conductive surface, by thermal reaction of molecules containing reactive groups in an organic solvent or in aqueous solution. The thermal reaction may be produced under a variety of conditions. Methods of the present invention produce organic films attached Onto the surface or substrate, the thickness of which is roughly equal to or greater than one molecular monolayer.

In some aspects, the present invention provides a method of treating a surface to promote binding of one or more molecules of interest to the surface, comprising the steps of: contacting the surface with an organic molecule comprising a thermally stable base, bearing one or more attachment groups configured to attach the organic molecule to the surface and one or more binding groups configured to bind the organic molecule to a subsequent material of interest and; and heating the organic molecule and surface to a temperature of at least 25° C. wherein the organic molecules attach to the surface, and exhibit enhanced affinity for binding the subsequent material of interest.

In another aspect, the present invention provide a coating or film, comprising: one or more organic molecules, said organic molecule comprising a thermally stable base unit, one or more attachment groups configured to attach to a surface, and one or more binding groups. Of particular advantage, coatings or films of the present invention may be used in a large variety of applications to coat surfaces in a wide range of devices. For example, the one or more binding groups, may be configured to bind to one or more biocompatible compounds to form a biocompatible coating. Alternatively, the one or more binding groups are configured to bind to one or more hydrophilic compounds to form a hydrophilic coating or conversely, a hydrophobic compound to render the surface more hydrophobic. In some embodiments, the one or more binding groups are configured to bind to one or more corrosive resistant compounds to form a corrosive resistant coating. In additional embodiments, the one or more binding groups are configured to bind to one or more compounds exhibiting optical absorption properties. In further aspects, the one or more binding groups may be configured to bind to one or more compounds exhibiting negative refractive index to form a stealth coating.

In addition, methods of the present invention make it possible to manufacture organic films that can simultaneously provide protection against the external medium, for example against corrosion, and/or offer a attached coating that has organic functional groups such as those mentioned above and/or promote or maintain electrical conductivity at the surface of the treated objects.

It is thus also possible by methods of the present invention, to manufacture multilayer conductive structures, for example by using organic intercalating films based on the present invention.

In some embodiments the organic films obtained according to the present invention constitute an attached protective coating, which withstands anodic potentials above the corrosion potential of the conductive surface to which they have been attached.

Methods of the present invention may also comprise, for example, a step of depositing a film of a vinyl polymer by thermal polymerization of the corresponding vinyl monomer on the conductive polymer film.

Methods of the present invention may also be used to produce very strong organic/conductor interfaces. Specifically, the organic films of the present invention are conductive at any thickness. When they are sparingly crosslinked, they can constitute “conductive sponges”, with a conductive surface whose apparent area is very much greater than the original surface onto which they are attached. This makes it possible to produce a more dense molecule attachment than on the starting surface onto which they are attached.

The present invention consequently makes it possible to produce attached and conductive organic coatings, of adjustable thickness, on conductive or semiconductive surfaces.

Methods of the present invention can be used, for example, to protect non-noble metals against external attack, such as those produced by chemical agents, such as corrosion, etc. This novel protection imparted by means of the process of the invention can, for example, prove to be particularly advantageous in connections or contacts, where the electrical conduction properties are improved and/or conserved.

The present invention also makes it possible to strongly attach additional layers to metal layers. For example, a molecule layer may be deposited onto a metal substrate, and once bound, this molecule layer may serve to adhere additional metal layers, or to attach an insulating layer. There are many applications to this technology with examples in the semiconductor industry (i.e., using a molecular layer attached to a barrier metal on a semiconductor substrate to allow electroplating of copper), the printed circuit board industry (attaching a molecular film onto a copper metal layer, to act as an adhesion layer for subsequent deposition of epoxy or other insulating layers) and in general manufacturing processes (such as the deposition of plastics on metal substrates).

In another application, methods of the present invention can be used, for example, for the manufacture of covering attached sublayers, on all types of conductive or semiconductive surfaces, on which all types of molecule attachments may be performed, and especially those using electrochemistry, for instance the electro-deposition or electro-attaching of vinyl monomers, of strained rings, of diazonium salts, of carboxylic acid salts, of alkynes, of Grignard derivatives, etc. This sublayer can thus constitute a high-quality finishing for the remetallization of objects, or to attach functional groups, for example in the fields of biomedics, biotechnology, chemical sensors, instrumentation, etc.

Further, the present invention may thus be used, for example, in the manufacture of ah encapsulating coating for electronic components, in the manufacture of a hydrophilic coating, in the manufacture of a biocompatibles coating, for the manufacture of a film that can be used as an adhesion primer; as an organic post-molecule attachment support, as a coating with optical absorption properties or as a coating with stealth properties.

In one application the present invention may be used to provide a molecular adhesion layer for electroplating of metals. In one instance, molecules are attached to printed circuit board substrates, such as polymer, epoxy or carbon coated substrates to provide a seed layer for electroless plating of a metal, such as electroless copper plating. According to teaching of the present invention, such molecules exhibit a strong bond to the organic substrate, and/or a strong organic-Cu bond. The high affinity of the attached molecule, facilitates electroless plating of the copper, which is then used as a seed layer to electroplate larger quantities of copper.

In one embodiment, the film has the property that it stabilizes the deposition of elements used for electroplating (e.g., Cu, Ni, Pd) and provides a more suitable substrate for electroplating than the original surface.

In some embodiments, methods of the present invention are performed by thermally-induced; reaction of at least one thermally-stable molecular species that is a precursor of the said organic film, comprising the steps of attaching and growing the film by contacting the molecular species with a surface, either in solution or via chemical vapor deposition, heating the surface to induce a chemical reaction which binds the molecule to the surface, then washing off the excess through addition and removal of a solvent which can dissolve the unreacted molecules. This may be followed by further treatment, for example by electroplating of a desired metal Utilizing conventional procedures. The attached molecule stabilizes the metal ion on the surface and promotes electroplating. Alternatively, further treatment may not be needed. For example the method may produce the final product such as an anti-corrosive coating or a bio-compatible coating on a suitable substrate.

In one aspect the present invention provides methods of treating a surface by attaching molecular species to surfaces such as but not limited to electronic material surfaces. In some embodiments the molecules include porphyrins and related species. The electronic materials include without limitation: silicon, silicon oxide, silicon nitride, metals, metal oxides, metal nitrides and printed circuit board substrates, including carbon-based materials such as polymers and epoxies. Other surfaces include without limitation sensor, substrates, materials useful for biomedical devices such as plastics and sensors, and photovoltaic and solar cell substrates. The attachment procedure is simple, can be completed in short times, requires minimal amounts of material, is compatible with diverse molecular functional groups, and in some instances affords unprecedented attachment motifs. These features greatly enhance the integration of the molecular materials into the processing steps that are needed to complete the plating process.

In one embodiment, this invention provides a method of coupling an organic molecule to a surface of a Group II, III, IV, V, or VI element or to a semiconductor comprising a Group II, III, IV, V, or VI element (more preferably to a material comprising a Group III, IV, or V element) or to a transition metal, transition metal oxide or nitride and/or to an alloy comprising a transition metal or to another metal.

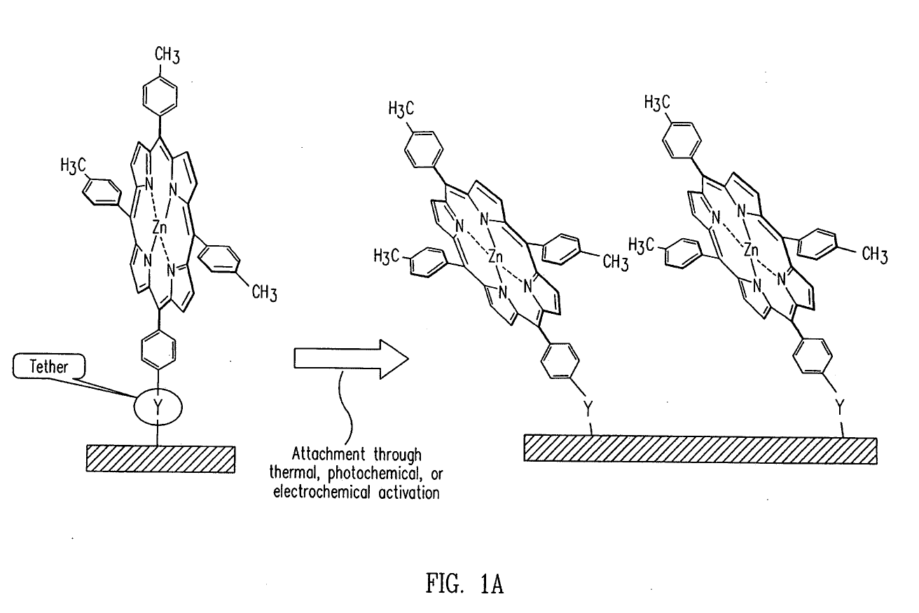

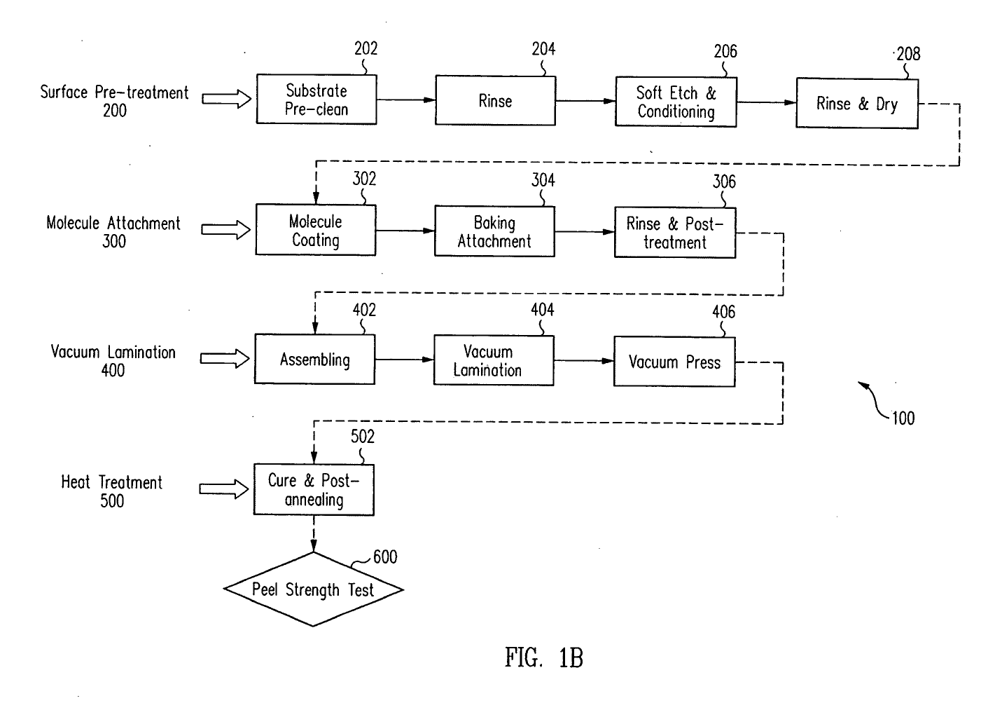

In certain embodiments as illustrated generally in FIG. 1A, the present invention provides methods of treating a surface by coupling a molecule to a surface. In general, a molecule is attached to a substrate via “tether” group Y via thermal, photochemical or electrochemical activation. FIG. 1B illustrates one embodiment of an exemplary method 100 of the present invention wherein a molecular is attached to a metal layer thereby modifying the metal layer and subsequently an epoxy substrate is laminated to the modified metal layer. In some embodiments this exemplary method generally includes surface pretreatment 200, molecule attachment 300, vacuum lamination 400, and optional heat treatment 500. FIG. 1B also shows where in the process peel strength testing 600 is carried out, however this step is shown only to illustrate the testing procedures and protocol used. Of course it should be understood that the broad method steps of the present invention do not include the peel strength test step 600.

Referring again to FIG. 1B; the method is carried out by optional pre-cleaning of the substrate at 202, rinsing 204, soft etch and conditioning 206, followed by rinse and drying of the surface 208. In this particular embodiment the substrate typically includes a metal layer formed thereon. The molecule(s) is then attached to the metal surface by coating, depositing, or contacting the one or more molecules with the substrate at 302, optionally heating or baking the substrate to promote attachment of the molecules to the substrate at step 304, and then rinsing the substrate and optional post treatment 306.

Next, the epoxy layer is attached to the layer of molecules, typically by lamination. In the exemplary embodiment vacuum lamination is shown, however the invention is not limited to any one particular lamination process. First, the expoxy layer is assembled on the layer of molecules at step 402, then vacuum laminated 404 and an optional vacuum press is applied 406.

Optionally, post treatment such as heat treatment may be used, such as curing and/or post annealing at step 502. Devices formed by the above described method may then be test for peel strength as shown at step 600.

In some embodiments the method includes optionally cleaning and/or pretreating the surface, coating or depositing one or more heat-resistant organic molecules bearing an attachment group; attaching the molecule to the surface through thermal, photochemical or electrochemical activation (for example without limitation this step may be accomplished by heating the molecule(s) or mixture of different molecules and/or the surface to a temperature of at least about 25° C.); and optionally post rinse and/or treatment of the surface. In certain embodiments, the organic molecule(s) are electrically coupled to the surface. In other embodiments the molecules are covalently linked to the surface. The method can, optionally, be performed under an inert atmosphere (e.g. Ar, N₂). In certain embodiments, molecule attachment comprises heating the molecule(s) to a gas phase and the contacting comprises contacting the gas phase to the surface. In certain embodiments, molecule attachment comprises heating the molecule(s) and/or the surface while the molecule is in contact with the surface. In certain embodiments, molecule attachment comprises applying the molecule(s) to the surface and then simultaneously or subsequently heating the molecule(s) and/or surface. The organic molecule(s) can be provided in a solvent or dry, or in gas phase, or otherwise not in a solvent. The molecule can be placed into contact with the surface by dipping in a solution of the molecule, spraying a solution of the molecule, ink-jet printing, or vapor deposition of the molecule directly onto the surface. Methods of the present invention are also suited for treating and forming films or coatings on non-planar surfaces. For example, the organic molecules may be attached to patterned, structured, curved or other non-planar surfaces and substrates.

In certain embodiments where attachment of the molecule is accomplished by thermal activation, heating is to a temperature of at least about 25° C., preferably at least about 50° C., more preferably at least about 100° C., and most preferably at least about 150° C. Heating can be accomplished by any convenient method, e.g. in an oven, on a hot plate, in a CVD device, in a plasma assisted CVD device, in an MBE device, and the like. In some embodiments the surface comprises PCB substrates such as polymer and carbon materials, including but not limited to epoxy, glass reinforced epoxy, phenol, polyimide, glass reinforced polyimide, cyanate, esters, Teflon, and the like. In other embodiments, the surface comprises a material selected from the group consisting of a Group III element, a Group IV element, a Group. V element, a semiconductor comprising a Group III element, a semiconductor comprising a Group IV element, a semiconductor comprising a Group V element, a transition metal, and a transition metal oxide. In other embodiments, the surface comprises a photovoltaic or solar cell device. In some embodiments, the photovoltaic or solar cell device may have a surface comprised of any one of more of; silicon, crystalline silicon, amorphous silicon, single-crystalline silicon, poly-crystalline silicon, microcrystalline silicon, nanocrystalline silicon, CdTe, copper indium gallium diselinide (CIGS), Group III-V semiconductor material, and combinations thereof.

In other embodiments, certain preferred surfaces comprise one or more of the following: tungsten, tantalum, and niobium, Au, Ag, Cu, Al, Ta, Ti, Ru, Ir, Pt, Pd, Os, Mn, Hf, Zr, V, Nb, La, Y, Gd, Sr, Ba, Cs, Cr, Co, Ni, Zn, Ga, In, Cd, Rh, Re, W, Mo, and oxides, alloys, mixtures, and/or nitrides thereof. In certain embodiments, the surface comprises a Group III, IV, or V, and/or a doped Group III, IV, or V element, e.g. silicon, germanium, doped silicon, doped germanium, and the like. The surface can, optionally, be a hydrogen passivated surface.

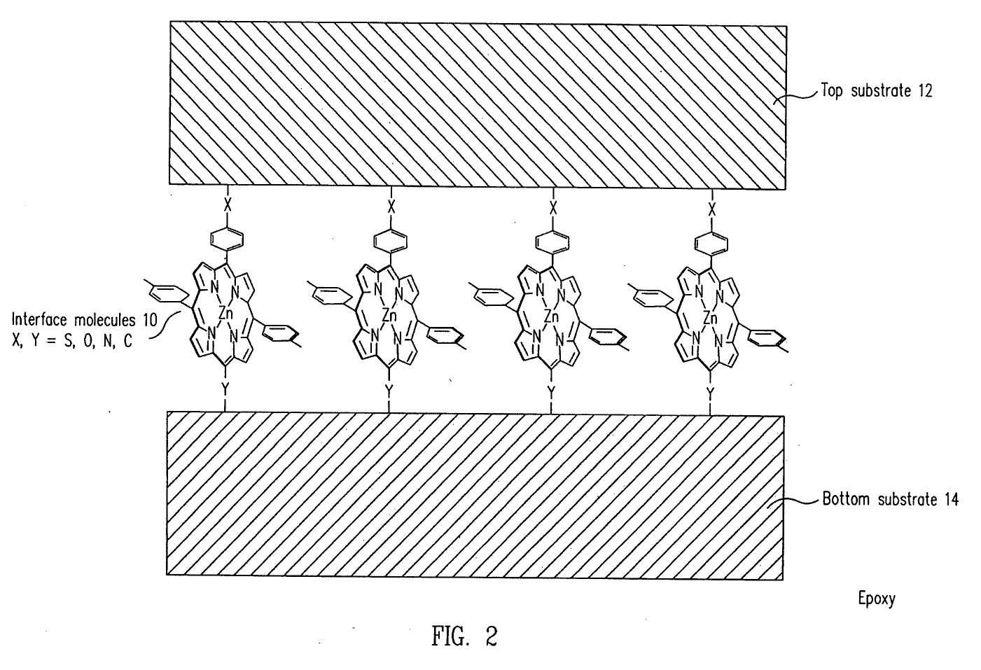

In general, organic molecules of the present invention are comprised of a thermally stable or heat resistant unit or base having brie or more binding groups X and one or more attachment groups Y as shown in FIG. 2. In certain embodiments, the heat-resistant molecule is a metal-binding molecule selected from any one or more of: a porphyrin, a porphyrinic macrocycle, an expanded porphyrin, a contracted porphyrin, a linear porphyrin polymer, a porphyrinic sandwich coordination complex, or a porphyrin array.

In general, in some embodiments the organic molecule is comprised of a thermally stable unit or base with one more binding groups X and one or more attachment groups Y. In certain embodiments, the organic molecule is heat-resistant metal-binding molecule, and may be comprised of one or more “surface active moieties,” also referred to in associated applications as “redox active moieties” or “ReAMs”. One embodiment of the invention encompasses the use of compositions of molecular components using surface active moieties generally described in U.S. Pat. Nos. 6,208,553, 6,381,169, 6,657,884, 6,324,091, 6,272,038, 6,212,093, 6,451,942, 6,777,516, 6,674,121, 6,642,376, 6,728,129, US Publication Nos: 20070108438, 20060092687, 20050243597, 20060209587 20060195296 20060092687 20060081950 20050270820 20050243597 20050207208 20050185447 20050162895 20050062097 20050041494 20030169618 20030111670 20030081463 20020180446 20020154535 20020076714, 2002/0180446, 2003/0082444, 2003/0081463, 2004/0115524, 2004/0150465, 2004/0120180, 2002/010589, U.S. Ser. Nos. 10/766,304, 10/834,630, 10/628,868, 10/456,321, 10/723,315, 10/800,147, 10/795,904, 10/754,257, 60/687,464, all of which are expressly incorporated in their entirety. Note that while in the associated applications listed immediately above, the heat-resistant molecule is sometime referred to as “redox active moieties” or “ReAMs,” in the instant application term surface active moiety is more appropriate. In general, in some embodiments there are several types of surface active moieties useful in the present invention, all based on polydentate proligands, including macrocyclic and non-macrocyclic moieties. A number of suitable proligands and complexes, as well as suitable substituents, are outlined in the references cited above. In addition, many polydentate proligands can include substitution groups (often referred to as “R” groups herein and within the cited references, and include moieties and definitions outlined in U.S. Pub. No. 2007/0108438, incorporated by reference herein specifically for the definition of the substituent groups.

Suitable proligands fall into two categories: ligands which use nitrogen, oxygen, sulfur, carbon or phosphorus atoms (depending on the metal ion) as the coordination atoms (generally referred to in the literature as sigma (a) donors) and organometallic ligands such as metallocene ligands (generally referred to in the literature as pi donors, and depicted in U.S. Pub. No. 2007/0108438 as Lm).

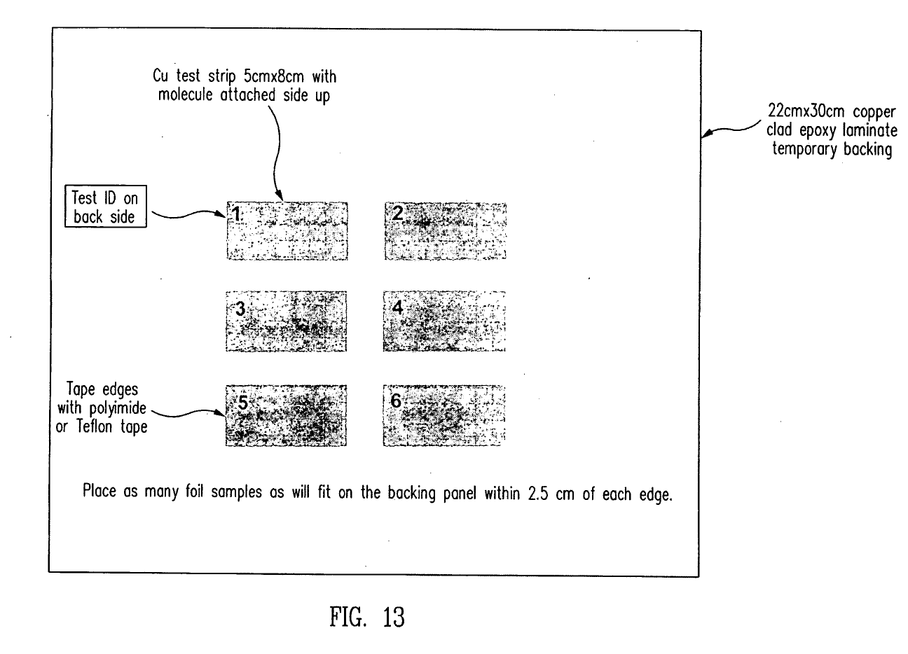

In addition, a single surface active moiety, may have two or more redox active subunits, for example, as shown in FIG. 13A of U.S. Pub. No. 2007/0108438, which utilizes porphyrins and ferrocenes.

In some embodiments, the surface active moiety is a macrocyclic ligand, which includes both macrocyclic proligands and macrocyclic complexes. By “macrocyclic proligand” herein is meant a cyclic compound which contains donor atoms (sometimes referred to herein as “coordination atoms”) oriented so that they can bind to a metal ion and which are large enough to encircle the metal atom. In general, the donor atoms are heteroatoms including, but not limited to, nitrogen; oxygen and sulfur, with the former being especially preferred. However, as will be appreciated by those in the art, different metal ions bind preferentially to different heteroatoms, and thus the heteroatoms used can depend on the desired metal ion. In addition, in some embodiments, a single macrocycle can contain heteroatoms of different types:

A “macrocyclic complex” is a macrocyclic proligand with at least one metal ion; in some embodiments the macrocyclic complex comprises a single metal ion, although as described below, polynucleate complexes, including polynucleate macrocyclic complexes, are also contemplated.

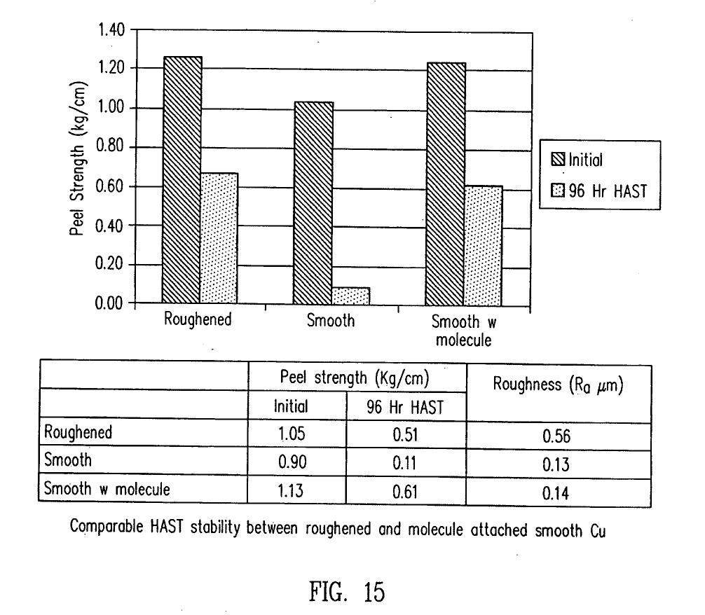

A wide variety of macrocyclic ligands find use in the present invention, including those that are electronically conjugated and those that may not be. A broad schematic of a suitable macrocyclic ligand is shown and described in FIG. 15 of U.S. Pub. No. 2007/0108438. In some embodiments, the rings, bonds and substitutents are chosen to, result in the compound being electronically conjugated, and at a minimum to have at least two oxidation states.

In some embodiments, the macrocyclic ligands of the invention are selected from the group consisting of porphyrins (particularly porphyrin derivatives as defined below), and cyclen derivatives. A particularly preferred subset of macrocycles suitable in the invention are porphyrins, including porphyrin derivatives. Such derivatives include porphyrins with extra rings ortho-fused, or ortho-perifused, to the porphyrin nucleus, porphyrins having a replacement of one or more carbon atoms of the porphyrin ring by an atom of another element (skeletal replacement), derivatives having a replacement of a nitrogen atom of the porphyrin ring by an atom of another element (skeletal replacement of nitrogen), derivatives having substituents other than hydrogen located at the peripheral meso-, 3- or core atoms of the porphyrin, derivatives with saturation of one or more bonds of the porphyrin (hydroporphyrins, e.g., chlorins, bacteriochlorins, isobacteriochlorins, decahydroporphyrins, corphins, pyrrocorphins, etc.), derivatives having one or more atoms, including pyrrolic and pyrromethenyl units, inserted in the porphyrin ring (expanded porphyrins), derivatives having one or more groups removed from the porphyrin ring (contracted porphyrins, e.g., corrin, corrole) and combinations of the foregoing derivatives (e.g. phthalocyanines, sub-phthalocyanines, and porphyrin isomers). Additional suitable porphyrin derivatives include, but are not limited to the chlorophyll group, including etiophyllin, pyrroporphyrin, rhodoporphyrin, phylloporphyrin, phylloerythrin, chlorophyll a and b, as well as the hemoglobin group, including deuterpporphyrin, deuterohemin, hemin, hematin, protoporphyrin, mesohemin, hematoporphyrin mesoporphyrin, coproporphyrin, uruporphyrin and turacin, and the series of tetraarylazadipyrromethines.

As will be appreciated by those in the art, each unsaturated position, whether carbon or heteroatom, can include one or more substitution groups as defined herein, depending on the desired valency of the system.

In addition, included within the definition of “porphyrin” are porphyrin complexes, which comprise the porphyrin proligand and at least one metal ion. Suitable metals for the porphyrin compounds will depend on the heteroatoms used as coordination atoms, but in general are selected from transition metal ions. The term “transition metals” as used herein typically refers to the 38 elements in groups 3 through 12 of the periodic table. Typically transition metals are characterized by the fact that their valence electrons, or the electrons they use to combine with other elements, are present in more than one shell and consequently often exhibit several common oxidation states. In certain embodiments, the transition metals of this invention include, but are not limited to one or more of scandium, titanium, vanadium, chromium, manganese, iron, cobalt, nickel, copper, zinc, yttrium, zirconium, niobium, molybdenum, technetium, ruthenium, rhodium, palladium, silver, cadmium; hafnium, tantalum, tungsten, rhenium, osmium, iridium, platinum, palladium, gold, mercury, rutherfordium, and/or oxides, and/or nitrides, and/or alloys, and/or mixtures thereof.

There are also a number of macrocycles based on cyclen derivatives. FIG. 17 13C of U.S. Pub. No. 2007/0108438, depicts a number of macrocyclic proligands loosely based on cyclen/cyclam derivatives, which can include skeletal expansion by the inclusion of independently selected carbons or heteroatoms. In some embodiments, at least one R group is a surface active subunit, preferably electronically conjugated to the metal. In some embodiments, including when at least one R group is a surface active subunit, two or more neighboring R2 groups form cyclo or an aryl group. In the present invention, the at least on R group is a surface active subunit or moiety.

Furthermore, in some embodiments, macrocyclic complexes relying organometallic ligands are used. In addition to purely organic compounds for use as surface active moieties, and various transition metal coordination complexes with 8-bonded organic ligand with donor atoms as heterocyclic or exocyclic substituents, there is available a wide variety of transition metal organometallic compounds with pi-bonded organic ligands (see Advanced Inorganic Chemistry, 5th Ed. Cotton & Wilkinson, John Wiley & Sons, 1988, chapter 26; Organometallics, A Concise Introduction, Elschenbroich et al., 2nd Ed., 1992, 30 VCH; and Comprehensive Organometallic Chemistry II, A Review of the Literature 1982-1994, Abel et al. Ed., Vol. 7, chapters 7, 8, 1.0 & 11, Pergamon Press, hereby expressly incorporated by reference). Such organometallic ligands include cyclic aromatic compounds such as the cyclopentadienide ion [C₅H₅(−1)] and various ring substituted and ring fused derivatives, such as the indenylide (−1) ion, that yield a class of bis(cyclopentadieyl) metal compounds, (i.e. the metallocenes); see for example Robins et al., J. Am, Chem. Soc. 104:1882-1893 (1982); and Gassman et al., J. Am. Chem. Soc. 108:4228-4229 (1986), incorporated by reference. Of these, ferrocene [(C₅H₅)₂Fe] and its derivatives are prototypical examples which have been used in a wide variety of chemical (Connelly et al., Chem. Rev. 96:877-910 (1996), incorporated by reference) and electrochemical (Geiger et al., Advances in Organometallic Chemistry 23:1-93; and Geiger et al., Advances in Organometallic Chemistry 24:87, incorporated by reference) reactions. Other potentially suitable organometallic ligands include cyclic arenes such as benzene, to yield bis(arene) metal compounds and their ring substituted and ring fused derivatives, of which bis(benzene)chromium is a prototypical example. Other acyclic n-bonded ligands such as the allyl(−1) ion, or butadiene yield potentially suitable organometallic compounds, and all such ligands, in conjunction with other 7c-bonded and 8-bonded ligands constitute the general class of organometallic compounds in which there is a metal to carbon bond. Electrochemical studies of various dimers and oligomers of such compounds with bridging organic ligands, and additional non-bridging ligands, as well as with and without metal-metal bonds are all useful.

In some embodiments, the surface active moieties are sandwich coordination complexes. The terms “sandwich coordination compound” or “sandwich coordination complex” refer to a compound of the formula L-Mn-L, where each L is a heterocyclic ligand (as described below), each M is a metal, n is 2 or more, most preferably 2 or 3, and each metal is positioned between a pair of ligands and bonded to one or more hetero atom (and typically a plurality of hetero atoms, e.g., 2, 3, 4, 5) in each ligand (depending upon the oxidation state of the metal). Thus sandwich coordination compounds are not organometallic compounds such as ferrocene, in which the metal is bonded to carbon atoms. The ligands in the sandwich coordination compound are generally arranged in a stacked orientation (i.e., are generally cofacially oriented and axially aligned with one another, although they may or may not be rotated about that axis with respect to one another) (see, e.g., Ng and Jiang (1997) Chemical Society Reviews 26:433-442) incorporated by reference. Sandwich coordination complexes include, but are not limited to “double-decker sandwich coordination compound” and “triple-decker sandwich coordination compounds”. The synthesis and use of sandwich coordination compounds is described in detail in U.S. Pat. Nos. 6,212,093; 6,451,942; 6,777,516; and polymerization of these molecules is described in WO 2005/086826, all of which are included herein, particularly the individual substituted, groups that find use in both sandwich complexes and the “single macrocycle” complexes.

In addition, polymers Of these sandwich compounds are also of use; this includes “dyads” and “triads” as described in U.S. Pat. Nos. 6,212,093; 6,451,942; 6,777,516; and polymerization of these molecules as described in WO 2005/086826, all of which are incorporated by reference and included herein.

Surface active moieties comprising non-macrocyclic chelators are bound to metal ions to form non-macrocyclic chelate compounds, since the presence of the metal allows for multiple proligands to bind together to give multiple oxidation states.

In some embodiments, nitrogen donating proligands are used. Suitable nitrogen donating proligands are well known in the art and include, but are not limited to, NH2; NFIR; NRR′; pyridine; pyrazine; isonicotinamide; imidazole; bipyridine and substituted derivatives of bipyridine; terpyridine and substituted derivatives; phenanthrolines, particularly 1,10-phenanthroline (abbreviated phen) and substituted derivatives of phenanthrolines such as 4,7-dimethylphenanthroline and dipyridol[3,2-a:2′,3′-c]phenazine (abbreviated dppz); dipyridophenazine; 1,4,5,8,9,12-hexaazatriphenylene (abbreviated hat); 9,10-phenanethrenequinone diimine (abbreviated phi); 1,4,5,8-tetraazaphenanthrene (abbreviated tap); 1,4,8,11-tetra-azacyclotetradecane (abbreviated cyclam) and isocyanide. Substituted derivatives, including fused derivatives, may also be used. It should be noted that macrocytic ligands that do not coordinatively saturate the metal ion, and which require the addition of another proligand, are considered non-macrocyclic for this purpose. As will be appreciated by those in the art, it is possible to covalent attach a number of “non-macrocyclic” ligands to form a coordinatively saturated compound, but that is lacking a cyclic skeleton.

Suitable sigma donating ligands using carbon, oxygen, sulfur and phosphorus are known in the art. For example, suitable sigma carbon donors are found in Gorton and Wilkenson, Advanced Organic Chemistry, 5th Edition, John Wiley & Sons, 1988, hereby incorporated by reference; seepage 38, for example. Similarly, suitable oxygen ligands include crown ethers, water and others known in the art. Phosphines and substituted phosphines are also suitable; see page 38 of Cotton and Wilkenson.

The oxygen, sulfur, phosphorus and nitrogen-donating ligands are attached in such a manner as to allow the heteroatoms to serve as coordination atoms.

In addition, some embodiments utilize polydentate ligands that are polynucleating ligands, e.g. they are capable of binding more than one metal ion. These may be macrocyclic or non-macrocyclic.

The molecular elements herein may also comprise polymers of the surface active moieties as outlined above; for example, porphyrin polymers (including polymers of porphyrin complexes), macrocycle complex polymers, surface active moieties comprising two surface active subunits, etc. can be utilized. The polymers can be homopolymers or heteropolymers, and can include any number of different mixtures (admixtures) of monomeric surface active moiety, wherein “monomer” Can also include surface active moieties comprising two or more subunits (e.g. a sandwich coordination compound, a porphyrin derivative substituted with one or more ferrocenes, etc.). Surface active moiety polymers are described in WO 2005/086826, which is expressly incorporated by reference in its entirety.

In certain embodiments, the attachment group Y comprises an aryl functional group and/or an alkyl attachment group. In certain embodiments, the aryl functional group comprises a functional group selected from the group consisting of amino, alkylamino, bromo, iodo, hydroxy, hydroxymethyl, formyl, bromomethyl, vinyl, allyl, S-acetylthiomethyl, Se-acetylselenomethyl, ethynyl, 2-(trimethylsilyl)ethynyl, mercapto, mercaptomethyl, 4,4,5,5-tetramethyl-1,3,2-dioxaborolan-2-yl, and dihydroxyphosphoryl. In certain embodiments, the alkyl attachment group comprises a functional group selected from the group consisting of bromo, iodo, hydroxy, formyl, vinyl, mercapto, selenyl, S-acetylthio, Se-acetylseleno, ethynyl, 2-(trimethylsilyl)ethynyl, 4,4,5,5-tetramethyl-1,3,2-dioxaborolan-2-yl, and dihydroxyphosphoryl. In certain embodiments, the attachment group comprises an alcohol or a phosphonate.

In certain embodiments, the contacting step comprises selectively contacting the organic molecule to certain regions of the surface and not to other regions. For example, the contacting can comprise selectively contacting the organic molecule to certain regions of the surface and not to other regions. In certain embodiments, the contacting comprises placing a protective coating (e.g. a masking material) on the surface in regions where the organic molecule(s) are not to be attached; contacting the molecule(s) with the surface; and removing the protective coating to provide regions of the surface without the organic molecule(s). In certain embodiments, the contacting comprises contact printing of a solution, comprising the organic molecule(s) or the dry organic molecule(s) onto the surface. In certain embodiments, the contacting comprises spraying or dropping a solution comprising the organic molecule(s) or applying the dry organic molecule(s) onto the surface. In certain embodiments, the contacting comprises contacting the surface with the molecule(s) and subsequently etching selected regions of the surface to remove the organic molecule(s). In certain embodiments, the contacting comprises molecular beam epitaxy (MBE), and/or chemical vapor deposition (CVD), and/or plasma-assisted vapor deposition, and/or sputtering and the like. In certain embodiments, the heat-resistant organic molecule comprises a mixture at least two different-species of heat-resistant organic molecule and the heating comprises heating the mixture and/or the surface.

This invention also provides a method of coupling a metal-binding molecule (or a collection of different species of metal-binding molecules) to a surface. In some embodiments the method comprises heating the molecule(s) to a gas phase; and contacting the molecule(s) to a surface whereby the metal-binding molecule(s) couple to the surface. In certain embodiments, the metal-binding molecule is chemically coupled to the surface and/or electrically coupled to the surface. In certain embodiments, the heating is to a temperature of at least about 25° C., preferably at least about 50° C., more preferably at least about 100° C., and most preferably at least about 150° C. Heating can be accomplished by any convenient method, e.g. in an oven, on a hot plate, in a furnace, rapid thermal processing furnace, in a CVD device, plasma assisted CVD device, in an MBE device, and the like.

In certain embodiments, the surface can comprise a material selected from the group consisting of a Group III element, a Group IV element, a Group V element, a semiconductor comprising a Group III element, a semiconductor comprising a Group IV element, a semiconductor comprising a Group V element, a transition metal, a transition metal oxide, a plastic material, epoxy, ceramic, carbon material and the like as described above. In certain embodiments, the surface comprises a material such as Au, Ag, Cu, Al, Ta, Ti, Ru, Ir, Pt, Pd, Os, Mn, Hf, Zr, V, Nb, La, Y, Gd, Sr, Ba, Cs, Cr, Co, Ni, Zn, Ga, In, Cd, Rh, Re, W, Mo, and/or oxides, nitrides, mixtures, or alloys thereof. In certain embodiments, the metal-binding molecule includes, but is not limited to any of the molecules described herein. Similarly the attachment groups include, but are not limited to any of the attachment groups described herein. In certain embodiments, the Group II, III, IV, V, or VI element, more preferably a Group III, IV, or V, element; still more preferably a Group IV element or a doped Group IV element (e.g., silicon, germanium, doped silicon, doped germanium, etc.). In certain embodiments, the contacting comprises selectively contacting the volatilized organic molecule to certain regions of the surface and not to other regions. In certain embodiments, the contacting comprises: placing a protective coating on the surface in regions where the metal-binding molecule is not to be attached; contacting the molecule with the surface; and removing the protective coating to provide regions of the surface without the metal-binding molecule. In certain embodiments, the contacting comprises contacting the surface with the molecule and subsequently etching selected regions of the surface to remove the metal-binding molecule. In certain embodiments, the contacting comprises molecular beam epitaxy (MBE), and/or chemical vapor deposition (CVD), and/or plasma-assisted vapor deposition, and/or sputtering, and combinations thereof.

In another embodiment, this invention provides a surface of a Group II, III, IV, V, or VI element or a surface of a semiconductor comprising a Group II, III, IV, V, or VI or a transition metal, transition metal oxide, or nitride, or alloy, or mixture having an organic molecule coupled thereto, where the organic molecule is coupled to said surface by methods described herein. In certain embodiments, the organic molecule is a metal-binding molecule and includes, but is not limited to any of the molecules described herein. Similarly the attachment groups include, but are not limited to any of the attachment groups described herein. In certain embodiments, the Group II, III, IV, V, or VI element, more preferably a Group III, IV, or V, element, still more preferably a Group IV element or a doped Group IV element (e.g., silicon, germanium, doped silicon, doped germanium, etc.). In certain embodiments, the surface comprises a surface in or on one or more integrated circuit elements (e.g., a transistor, a capacitor, a memory element, a diode, a logic gate, a rectifier) or interconnects between such elements.

In another embodiment, this invention provides a method of fabricating an ordered molecular assembly as illustrated in FIG. 2. Of significant advantage, the molecules 10 provide an interface between a top 12 and bottom 14 substrate, that is the molecules are provided with attachment groups X and Y configured to bind to other materials or molecules of interest, such as the top 12 and bottom 14 substrates as shown in FIG. 2. In one embodiment, the top substrate 12 may bean epoxy material and bottom substrate 14 may be a metal such as copper to form a multilayered PCB board. Alternatively, the two substrates can be reversed in order. In one embodiment, attachment groups X and Y may be independently selected from any one or more of the chemical species described above.

In some embodiments, the method generally involves providing a heat-resistant organic molecule (or a plurality of different heat resistant organic molecules) derivatized with an attachment group; heating the molecule and/or a surface to a temperature of at least about 100° C.; where the surface comprises a Group III, IV, or V element or a transition metal or metal oxide, contacting the molecule(s) at a plurality of discrete locations on the surface whereby the attachment groups form bonds (such as but not limited to covalent or ionic bonds) with the surface at the plurality of discrete locations. In certain embodiments, the heating is to a temperature of at least about 25° C., preferably at least about 50° C., more preferably at least about 100° C., and most preferably at least about 150° C. In certain embodiments, the organic molecule is a metal-binding molecule and includes, but is not limited to any of the molecules described herein. Similarly the attachment groups include, but are not limited to any of the attachment groups described herein.

This invention also provide kits for coupling an organic molecule to a surface. The kits typically include a container containing a heat-resistant organic molecule derivatized with an attachment group (e.g., as described herein) and/or a binding group(s) for binding a particular molecule or molecules of interest, and optionally, instructional materials teaching coupling the organic molecule to the surface by heating, the molecule and/or the surface to a temperature of about 100° C. or more.

The process of the present invention also provides methods of treating non-conductive surfaces (such as epoxy, glass, SiO₂, SiN, etc) as well as conductive surfaces, such as copper, gold, platinum, etc., and to “non-noble” surfaces, such as surfaces containing reducible oxide, a graphite surface, a conductive or semiconductive organic surface, a surface of an alloy, a surface of one (or more) conventional conductive polymer(s), such as a surface based on pyrrole, on aniline, on thiophene, on EDOT, on acetylene or on polyaromatics, etc., a surface of an intrinsic or doped semiconductor, a photovoltaic surface, and any combination of these compounds and devices.

Mixtures of these various molecular compounds may also be used according to the present invention.

In addition, methods of the present invention makes it possible to manufacture organic films that can simultaneously provide protection against the external medium, for example against corrosion, and/or offer a attached coating that has organic functional groups such as those mentioned above and/or promote or maintain electrical conductivity at the surface of the treated objects.

It is thus also possible by methods of the present invention, to manufacture multilayer conductive structures, for example by using organic intercalating films based on the present invention.

In some embodiments the organic films obtained according to the present invention constitute an attached protective coating, which withstands anodic potentials above the corrosion potential of the conductive surface to which they have been attached.

Methods of the present invention may thus also comprise, for example, a step of depositing a film of a vinyl polymer by thermal polymerization of the corresponding vinyl monomer on the conductive polymer film.

Methods of the present invention may also be used to produce very strong organic/conductor interfaces. Specifically, the organic films of the present invention are conductive at any thickness. When they are sparingly crosslinked, they can constitute “conductive sponges”, with a conductive surface whose apparent area is very much greater than the original surface onto which they are attached. This makes it possible to produce a more dense molecule attachment than on the starting surface onto which they are attached.

The present invention consequently makes it possible to produce attached and conductive organic coatings, of adjustable thickness, on conductive or semiconductive surfaces.

Methods of the present invention can be used, for example, to protect non-noble metals against external attack, such as those produced by chemical agents, such as corrosion, etc. This novel protection imparted by means of the process of the invention can, for example, prove to be particularly advantageous in connections or contacts, where the electrical conduction properties are improved and/or conserved.

In another application, methods of the present invention can be used, for example, for the manufacture of covering attached-sublayers, on all types of conductive or semiconductive surfaces, on which all types of molecule attachments may be performed, and especially those using electrochemistry, for instance the electro-deposition or electro-attaching of vinyl monomers, of strained rings, of diazonium salts, of carboxylic acid salts, of alkynes, of Grignard derivatives, etc. This sublayer can thus constitute a high-quality finishing for the remetallization of objects, or to attach functional groups, for example in the fields of biomedics, biotechnology, chemical sensors, instrumentation, etc.

The present invention may thus be used, for example, in the manufacture of an encapsulating coating for electronic components, in the manufacture of a hydrophilic or hydrophobic coating, in the manufacture of a biocompatible coating, for the manufacture of a film that can be used as an adhesion primer, as an organic post-molecule attachment support, as a coating with optical absorption properties or as a coating with stealth properties.

In one application, the present invention may be used to provide a molecular adhesion layer for electroplating of metals. In one instance, molecules are attached to printed, circuit board substrates, such as polymer, epoxy or carbon coated substrates to provide a seed layer for electroless plating of a metal, such as electroless copper plating. According to teaching of the present invention, such molecules exhibit a strong bond to the organic substrate, and/or a strong organic-Cu bond. The high affinity of the attached molecule facilitates electroless plating of the copper, which is then used as a seed layer to electroplate larger quantities of copper.

After formation of defined structures on the substrate, in this one exemplary embodiment electroless plating procedures are used to form a first metallic coating over the substrate surfaces and electrolytic copper deposition is then used to enhance the thickness of the coating. Alternatively, electrolytic copper may be plated directly over a suitably prepared microvia as disclosed in any of U.S. Pat. Nos. 5,425,873; 5,207,888; and 4,919,768. The next step in the process comprises electroplating copper onto the thus prepared conductive microvias using an electroplating solution of the invention. A wide variety of substrates may be plated with the compositions of the invention, as discussed above. The compositions of the invention are particularly useful to plate difficult work pieces, such as circuit board substrates with small diameter, high aspect ratio microvias and other apertures. The plating compositions of the invention also will be particularly useful for plating integrated circuit devices, such as formed semiconductor devices and the like.

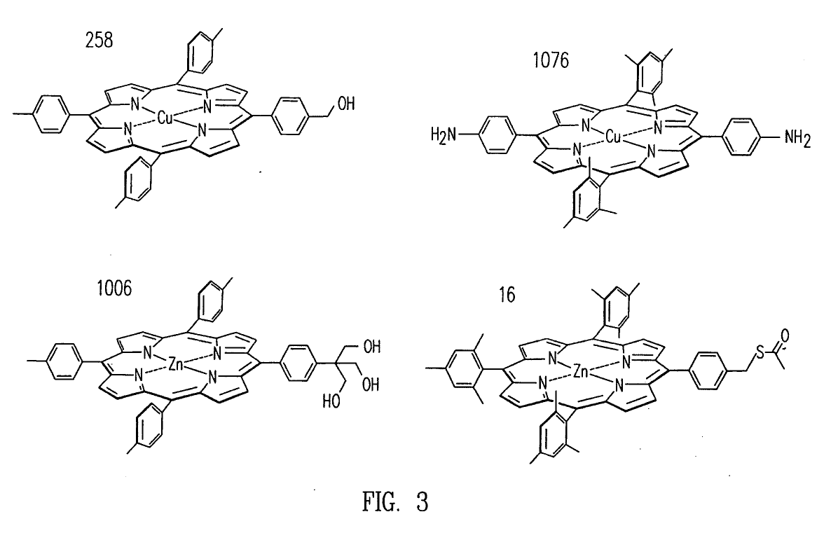

For example in some embodiments, the molecules will comprise binding group(s) X which promote favorable organic —Cu bonds. Examples of suitable binding groups X include but are not limited to thiols and amines, alcohols and ethers. The molecules further comprise attachment group(s) Y which promote favorable molecule-organic substrate bonds. Examples of suitable attachment groups Y include but are not limited to amines, alcohols, ethers, other nucleophile, phenyl ethynes, phenyl allylic groups and the like. According to embodiments of the present invention, and without limitation, some molecules suitable for surface treatment are shown in FIG. 3.

In another embodiment, a metal or metal nitride (e.g., Ti, Ta, TiN or TaN) surface is treated to attach molecules thereon that promote binding of certain materials useful as seed layers for copper electroplating. In this embodiment molecules are provided, that have attachment group(s) Y with a strong bond to TaN, and binding group(s) W that exhibit a strong organic-Cu bond. Preferably, the molecules will reduce electromigration, and the molecular layer is preferably thin and/or conductive, as high current densities will be conducted from barrier layer to Cu, including the organic layer. The attachment group(s) Y of the molecules would also preferably attach to TaO₂, since TaN; is likely to have some oxide once exposed to atmosphere:

Significantly, the present invention provides for selection of particular binding groups X and attachment groups Y depending upon the application. This allows one to practice the invention with a wide range of substrate materials, thus providing a flexible, robust process and a significant advance over conventional techniques. For example, organic molecules may be attached to Br-rich substrates. Further, the methods of the present invention may be practiced with substrates which have undergone surface treatment. For example, organic molecules may be attached to epoxy substrates having a partially roughened or oxidized surface. Additionally, organic molecules may be attached to partially cured epoxy substrates (residual epoxides).

Electroplating solutions of the invention generally comprise at least one soluble, copper salt, an electrolyte and a brightener component. More particularly, electroplating compositions of the invention preferably contain a copper salt; an electrolyte, preferably an acidic aqueous solution such as a sulfuric acid solution with a chloride or other halide ion source; and one or more brightener agents in enhanced concentrations as discussed above. Electroplating compositions of the invention also preferably contain a suppressor agent. The plating compositions also may contain other components such as one or more leveler agents and the like.

A variety of copper salts may be employed in the subject electroplating solutions, including for example copper sulfates, copper acetates, copper fluoroborate, and cupric nitrates. Copper sulfate pentahydrate is a particularly preferred copper salt. A copper salt may be suitably present in a relatively wide concentration range in the electroplating compositions of the invention. Preferably, a copper salt will be employed at a concentration of from about 10 to about 300 grams per liter of plating solution, more preferably at a concentration of from about 25 to about 200 grams per liter of plating solution, still more preferably at a concentration of from about 40 to about 175 grams per liter of plating solution.

Plating baths of the invention preferably employ an acidic electrolyte, which typically will be an acidic aqueous solution and that preferably contains a halide ion source, particularly a chloride ion source. Examples of suitable acids for the electrolyte include sulfuric acid, acetic acid, fluoroboric acid, methane sulfonic acid and sulfamic acid. Sulfuric acid is generally preferred. Chloride is a generally preferred halide ion. A wide range of halide ion concentrations (if a halide ion is employed) may be suitably utilized, e.g. from about 0 (where no halide ion employed) to 100 parts per million (ppm) of halide ion in the plating solution, more preferably from about 25 to about 75 ppm of halide ion source in the plating solution.

Embodiments of the invention also includes electroplating baths that are substantially or completely free of an added acid and may be neutral or essentially neutral (e.g. pH of at least less than about 8 or 8.5). Such plating compositions are suitably prepared in the same manner with the same components as other compositions disclosed herein but without an added acid. Thus, for instance, a preferred substantially neutral plating composition of the invention may have the same components as the plating bath of Example 1 which follows, but without the addition of sulfuric acid. A wide variety of brighteners, including known brightener agents, may be employed in the copper electroplating compositions of the invention. Typical brighteners contain one or more sulfur atoms, and typically without any nitrogen atoms and a molecular weight of about 1000 or less. In addition to the copper salts, electrolyte and brightener, plating baths of the invention optionally may contain a variety of other components, including organic additives such as suppressors agents, leveling agents and the like. Use of a suppressor agent in combination with an enhanced brightener concentration is particularly preferred and provides surprisingly enhanced plating performance, particularly in bottom-fill plating of small diameter and/or high aspect ratio microvias.

Use of one or more leveling agents in plating baths of the invention is generally preferred. Examples of suitable leveling agents are described and set forth in U.S. Pat. Nos. 3,770,598, 4,374,709, 4,376,685, 4,555,315 and 4,673,459. In general, useful leveling agents include those that contain a substituted amino group such as compounds having R—N—R′, where each R and R′ is independently a substituted or unsubstituted alkyl, group or a substituted or unsubstituted aryl group. Typically the alkyl groups have from 1 to 6 carbon atoms, more typically from 1 to 4 carbon atoms. Suitable aryl groups include substituted or unsubstituted phenyl or naphthyl. The substituents of the substituted alkyl and aryl groups may be, for example, alkyl, halo and alkoxy.

Other characteristics and advantages of the present invention will also become apparent to a person skilled in the art on reading the examples below, given as non-limiting illustrations, with reference to the attached figures.

Of particular advantage various parameters can be optimized for attachment of any particular organic molecule. This feature makes the invention suitable for a wide range of applications and uses. According to teachings of the present invention, parameters include (1) the concentration of the molecule(s), (2) the baking time, and (3) the baking temperature. These procedures typically use high concentrations of molecules in solution or neat molecules. The use of very small amounts of material indicates that relatively small amounts of organic solvents can be used, thereby minimizing environmental hazards.

In addition, baking times as short as a few minutes (e.g., typically from about 1 sec to about 1 hr, preferably from about 10 sec to about 30 min, more preferably from about 1 minute to about 15, 30, or 45 minutes, and most preferably from about 5 min to about 30 minutes) afford high surface coverage. Short times minimize the amount of energy that is used in the processing step.

Baking temperatures as high as 400° C. and greater can be used with no degradation of certain types of molecules. This result is of importance in that many processing steps in fabricating semiconductor devices entail high temperature processing. In certain embodiments, preferred baking temperatures range from about 25° C. to about 400° C., preferably from about 100° C. to about 200° C., more preferably from about 150° C. to about 250° C., and most preferably from about 150° C. to about 200° C.

Diverse functional groups on the organic molecules are suitable for use in attachment to silicon or other substrates (e.g. Group III, IV, or V elements, transition metals, transition metal oxides or nitrides, transition metal alloys, etc.). The attachment groups Y include, but are not limited to, amine, alcohol, ether, thiol, S-acetylthiol, bromomethyl, allyl, iodoaryl, carboxaldehyde, ethyne, vinyl, hydroxymethyl. It is also noted that groups such as ethyl, methyl, or arene afford essentially no attachment.

While in certain embodiments, heating is accomplished by placing the substrate in an oven, essentially any convenient heating method can be utilized, and appropriate heating and contacting methods can be optimized for particular (e.g., industrial) production contexts. Thus, for example, in certain embodiments; heating can be accomplished by dipping the surface in a hot solution containing the organic molecules that are to be attached. Local heating/patterning can be accomplished using for example a hot contact printer, or a laser. Heating can also be accomplished using forced air, a convection oven, radiant heating, and the like. The foregoing embodiments are intended to be illustrative rather than limiting.

In some embodiments the organic molecule is provided in a solvent, dispersion, emulsion, paste, gel, or the like. Preferred solvents, pastes, gels, emulsions, dispersions, etc., are solvents that can be applied to the Group II, III, IV, V, and/or VI material(s), and/or transition metals without substantially degrading that substrate and that solubilize or suspend, but do not degrade the organic molecule(s) that are to be coupled to the substrate. In certain embodiments, preferred solvents include high boiling point solvents (e.g., solvents with an initial boiling point greater than about 130° C., preferably greater than about 150° C., more preferably greater than about 180° C.). Such solvents include, but are not limited to benzonitrile, dimethylformamide, xylene, ortho-dichlorobenzene, and the like.

In some embodiments to effect attachment to a substrate (such as but not limited to a Group II, III, IV, V, or VI element, semiconductor, and/or oxide, and/or transition metal, transition metal oxide or nitride, epoxy or other polymer-based material, photovoltaic or solar cell and the like) the heat-resistant organic molecule, either bears one or more attachment group(s) Y (e.g., as substituent(s)) and/or is derivatized so that it is attached directly or through a linker to one or more attachment groups Y.

In certain preferred embodiments, the attachment group Y comprises an aryl or an alkyl group. Certain preferred aryl groups include a functional group such as amino, alkylamino, bromo, carboxylate, ester, amine, iodo, hydroxy, ether, hydroxymethyl, formyl, bromomethyl, vinyl, allyl, S-acetylthiomethyl, Se-acetylselenomethyl, ethynyl, 2-(trimethylsilyl)ethynyl, mercapto, mercaptomethyl, 4,4,5,5-tetramethyl-1,3,2-dioxaborolan-2-yl, and dihydroxyphosphoryl. Certain preferred alkyls include a functional group such as acetate, carbonyl, carboxylic acid, amine, epoxide bromo, iodo, hydroxy, formyl, vinyl, mercapto, selenyl, S-acetylthio, Se-acetylseleno, ethynyl, 2-(trimethylsilyl)ethynyl, 4,4,5,5-tetramethyl-1,3,2-dioxaborolan-2-yl, dihydroxyphosphoryl, and combinations thereof.

In certain embodiments the attachment groups Y include, but are not limited to alcohols, thiols, carboxylates, ethers, esters, S-acetylthiols, bromomethyls, allyls, iodoaryls, carboxaldehydes, ethynes, and the like. In certain embodiments, the attachment groups include, but are not limited to 4-(hydroxymethyl)phenyl, 4-(S-acetylthiomethyl)phenyl, 4-(Se-acetylselenomethyl)phenyl, 4-(mercaptomethyl)phenyl, 4-(hydroselenomethyl)phenyl, 4-formylphenyl, 4-(bromomethyl)phenyl, 4-vinylphenyl, 4-ethynylphenyl, 4-allylphenyl, 4-[2-(trimethylsilyl)ethynyl]phenyl, 4-[2-(triisopropylsilyl)ethynyl]phenyl, 4-bromophenyl, 4-iodophenyl, 4-hydroxyphenyl, 4-(4,4,5,5-tetramethyl-1,3,2-dioxaborolan-2-yl)phenyl bromo, iodo, hydroxymethyl, S-acetylthiomethyl, Se-acetylselenomethyl, mercaptomethyl, hydroselenomethyl, formyl, bromomethyl, chloromethyl, ethynyl, vinyl, allyl, 4-[2-(4-(hydroxymethyl)-phenyl)ethynyl]phenyl, 4-(ethynyl)biphen-4′-yl, 4-[2-(triisopropylsilyl)ethynyl]biphen-4′-yl, 3,5-diethynylphenyl, 2-bromoethyl, and the like. These attachment groups Y are meant to be illustrative and not limiting.

The suitability of other attachment groups Y can readily be evaluated. A heat-resistant organic molecule bearing the attachment group(s) of interest (directly or on a linker) is coupled to a substrate (e.g., epoxy) according to the methods described herein. The efficacy of attachment, can then be evaluated spectroscopically, e.g., using reflectance UV absorption measurements.

The attachment groups Y can be substituent(s) comprising the heat-resistant organic molecule. Alternatively, the organic molecule can be derivatized to [covalently] link the attachment group(s) thereto either directly or through a linker.

Means of derivatizing molecules, e.g., with alcohols or thiols are well known to those of skill in the art (see, e.g., Gryko et al. (1999) J. Org. Chem., 64:8635-8647; Smith and March (2001) March's Advanced Organic Chemistry, John Wiley & Sons, 5th Edition, etc.).

Where the attachment group Y comprises an amine, in certain embodiments, suitable amines include, but are not limited to a primary amine, a secondary amine, a tertiary amine, a benzyl amine, and an aryl amine. Certain particularly preferred amines include, but are not limited to 1 to 10 carbon straight chain amine, aniline, and phenethyl amine.

Where the attachment group Y comprises an alcohol, in certain embodiments, suitable alcohols include, but are not limited to a primary alcohol, a secondary alcohol, a tertiary alcohol, a benzyl alcohol, and an aryl alcohol (i.e., a phenol). Certain particularly preferred alcohols include, but are not limited to 2 to 10 carbon straight chain alcohols, benzyl alcohol, and phenethyl alcohol, or ether containing side groups.

When the attachment group Y comprises a thiol, in certain embodiments, suitable thiols include, but are not limited to a primary thiol, a secondary thiol, a tertiary thiol, a benzyl thiol, and an aryl thiol. Particularly preferred thiols include, but are not limited to 2 to 10 carbon straight chain thiols, benzyl thiol, and phenethyl thiol.

The surface can take essentially any form. For example, it can be provided as a planar substrate, an etched substrate, a deposited domain on another substrate and the like. Alternatively, the surface can be curved, or any other non-planar form. Particularly preferred forms include those forms of common use in solid state electronics, circuit board fabrication processes, sensor devices (both chemical and biological), medical devices and photovoltaic devices.

Although not necessarily required, in certain embodiments the surface is cleaned before and/or after molecule attachment use, e.g., using standard methods known to those of skill in the art. Thus, for example, in one preferred embodiment, the surface can be cleaned by sonication in a series of solvents (e.g., acetone, toluene, acetone, ethanol, and water) and then exposed to a standard wafer-cleaning solution (e.g., Piranha (sulfuric, acid: 30% hydrogen peroxide, 2:1)) at an elevated temperature (e.g., 100° C.). Various alkaline permanganate treatments have been used as standard methods for desmearing surfaces of printed circuit boards, including the through-holes. Such permanganate treatments have been employed for reliably removing wear and drilling debris, as well as for texturing or micro roughening the exposed epoxy resin surfaces. The latter effect significantly improves through-hole metallization by facilitating adhesion to epoxy resin, at the price of roughening the copper and decreasing the frequency response of the copper traces. Other conventional smear removal methods have included treatment with sulfuric acid, chromic acid, and plasma desmear, which is a dry chemical method in which boards are exposed to oxygen and fluorocarbon gases, e.g. CF4. Generally, permanganate treatments involve three different solution treatments used sequentially. They are (1) a solvent swell solution, (2) a permanganate desmear solution, and (3) a neutralization solution. Molecules may be reacted with an epoxy substrate that has been desmeared, and has oxidized functional groups available for reaction on the surface.

In certain embodiments, oxides can be removed from the substrate surface and the surface can be hydrogen passivated. A number of approaches to hydrogen passivation are well known to; those of skill in the art. For example, in one approach, a flow of molecular hydrogen is passed through dense microwave plasma across a magnetic field. The magnetic field serves to protect the sample surface from being bombarded by charged particles. Hence the crossed beam (CB) method makes it possible to avoid plasma etching and heavy ion bombardment that are so detrimental for many semiconductor devices (see, e.g., Balmashnov, et al. (1990) Semiconductor Science and Technology, 5:242). In one particularly preferred embodiment, passivation is by contacting the surface to be passivated with an ammonium fluoride solution (preferably purged of oxygen).

Other methods of cleaning and passivating surfaces are known to those of skill in the art (see, e.g., Choudhury (1997) The Handbook of Microlithography, Micromachining, and Microfabrication, Bard & Faulkner (1997) Fundamentals of Electrochemistry, Wiley, New York, and the like).

In certain embodiments, the heat-resistant organic molecules are attached to form a uniform or substantially uniform film across the surface of the substrate. In other embodiments, the organic molecules are separately coupled at one or more discrete locations on the surface. In certain embodiments, different molecules are coupled at different locations on the surface.

The location at which the molecules are coupled can be accomplished by any of a number of means. For example, in certain embodiments, the solution(s) comprising the organic molecule(s) can be selectively deposited at particular locations on the surface. In certain other embodiments, the solution can be uniformly deposited on the surface and selective domains can be heated. In certain embodiments, the organic molecules can be coupled to the entire surface and then selectively etched away from certain areas. Alternatively, the linker moiety can be designed to react selectively with specific functional groups on the substrate, allowing the molecule attachment process to act as the patterning step as well.

The most common approach to selectively contacting the surface with the organic molecule(s) involves masking the areas of the surface that are to be free of the organic molecules so that the solution or gas phase comprising the molecule(s) cannot come in contact with the surface in those areas. This is readily accomplished, by coating the substrate with a masking material (e.g., a polymer resist) and selectively etching the resist off of areas that are to be coupled. Alternatively a photoactivatible resist can be applied to the surface and selectively activated (e.g., via UV light) in areas that are to be protected. Such “photolithographic” methods are well known in the semiconductor industry (see e.g., Van Zant (2000) Microchip Fabrication: A Practical Guide to Semiconductor Processing; Nishi and Doering (2000) Handbook of Semiconductor Manufacturing Technology; Xiao (2000) Introduction to Semiconductor Manufacturing Technology, Campbell (1996) The Science and Engineering of Microelectronic Fabrication (Oxford Series in Electrical Engineering), Oxford University Press, and the like). In addition, the resist can be patterned on the surface simply by contact printing the resist onto the surface.

In other approaches, the surface is uniformly contacted with the molecules. The molecules can then be selectively etched off the surface in areas that are to be molecule free. Etching methods are well known to those of skill in the art and include, but are not limited to plasma etching, laser etching, acid etching, and the like.

Other approaches involve contact printing of the reagents, e.g., using a contact print head shaped to selectively deposit the reagent(s) in regions that are to be coupled, use of an inkjet apparatus (see e.g., U.S. Pat. No. 6,221,653) to selectively deposit reagents in particular areas, use of dams to selectively confine reagents to particular regions, and the like.

In certain preferred embodiments, the coupling reaction is repeated several times. After the reaction(s) are complete, uncoupled organic molecules are washed off of the surface, e.g., using standard wash steps (e.g., benzonitrile wash followed by sonication in dry methylene chloride). Additional surface cleaning steps (e.g. additional washes, descuming, or desmearing steps, and the like) may be used subsequent to molecule attachment to remove excess unreacted molecules prior to further treatment steps.

In one instance, a molecule comprising a porphyrin macrocycle with a central Cu metal was bonded to a TaN surface as described above. Molecules are selected for use based on their affinity to form a bond with the substrate, their thermal stability and their affinity for Cu²⁺ ions. The high affinity of the attached molecule facilitated electroless plating of the copper, which can then be used as a seed layer to electroplate larger quantities of copper.

In one non-limiting embodiment, namely the metal deposition or electroplating embodiment, electroplating on the molecule-covered substrate is accomplished as described above. Briefly, molecule coated substrates are: immersed in a plating bath containing appropriate levels of a copper salt, an electrolyte preferably an acidic aqueous solution such as a sulfuric acid solution with a chloride or other halide ion source, and one or more brightener agents in enhanced concentrations as discussed above, and preferably a suppressor agent. The plating compositions also may contain other components such as one or more leveler agents and the like. A cathodic voltage (e.g., −1 V) is applied to the molecule-covered substrate, causing the reduction of the Cu²⁺ ions to Cu⁰(s), which deposit on the molecular layer to form a metallic layer on top of the molecular layer. This copper layer has the same properties as a copper layer that is deposited in conventional protocols, and can be processed subsequently in similar ways, including lithographic patterning, damascene and dual-damascene processes.

### EXPERIMENTAL

A number of experiments were conducted as described below. These examples are shown for illustration purposes only and are not intended to limit the invention in any way.

### Examples

Referring again to FIG. 1B, in order to further illustrate the features of the present invention, an exemplary experimental process flow is schematically illustrated therein and comprises four major steps: (1) surface pre-treatment 200, (2) molecule attachment 300, (3) vacuum lamination 400, and (4) heat treatment 500. The specific data and results are shown for illustrative purposes only and are not intended to limit the scope of the invention in any way. FIG. 1B shows where in the process the peel strength tests are carried out, however this is shown only to illustrate the testing procedures. The broad method steps of the present invention do not include the peeling test steps.

In the exemplary experimental procedure shown in FIG. 1B, surface pretreatment is carried out by pre-cleaning 202, rinsing 204, soft etching and conditioning 206, and rinsing and drying the substrate 208.

Next molecule attachment is carried out by depositing or contacting the one or more molecules with the substrate 302, heating or baking the substrate to promote attachment of the molecules to the substrate 304, and then rinsing the substrate and post treatment 306.

Next vacuum lamination is carried out by assembling the laminate film over the molecule attached substrate 402, vacuum lamination 404, and optional vacuum press 406.

Next heat treatment is performed to cure or anneal the laminated assembly 502, which is then followed by peel strength testing 600.

### Example 1

### Molecule Attachment on a Metal Substrate

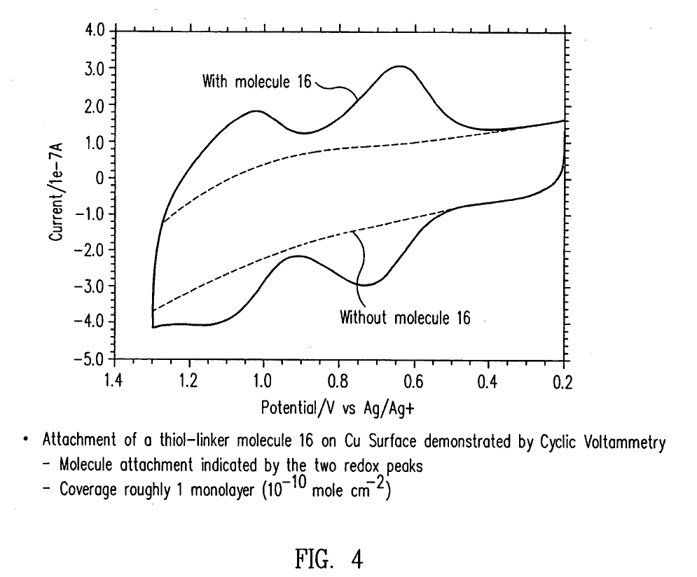

This example illustrates one exemplary approach to form a layer of organic molecules on a metal substrate. In this instance, a thiol-linker molecule 16 shown in FIG. 3, is attached to copper surface via the formation of C—S—Cu bond, as illustrated in FIGS. 1A and 2. A commercial copper wafer substrate was first cleaned by sonication for 5 minutes in acetone, water and then isopropyl alcohol. The substrate was coated with a solution containing 1 mM of the porphyrin molecule in ethanol by spin-coating. The sample was then baked at 150° C. for 5 minutes and followed by solvent rinse to remove the residual unreacted molecules. The amount of molecule attached can be adjusted by varying the concentration of the molecule, the attachment temperature, and duration, and quantified by Cyclic Voltammetry (CV) shown in FIG. 4, which is based on the redox property of porphyrin molecule as described in (Roth, K. M., Gryko, D. T. Clausen, C. Li, J., Lindsey, J. S., Kuhr, W. G. and Bocian, D. F. (2002). Comparison of Electron-Transfer and Charge-Retention Characteristics of Porphyrin-Containing Self-Assembled Monolayers Designed for Molecular Information Storage, J. Phys. Chem. B., 106, 8639-8648). The presence of an attached molecular layer is evidenced by the two pairs of characteristic CV peaks. The surface overage of molecules can be determined by integrating the charge under the CV peaks. In this case, it is approximately one monolayer (10⁻¹⁰ mole cm⁻²).

### Example 2

### Molecule Attachment on Semiconductor Substrates

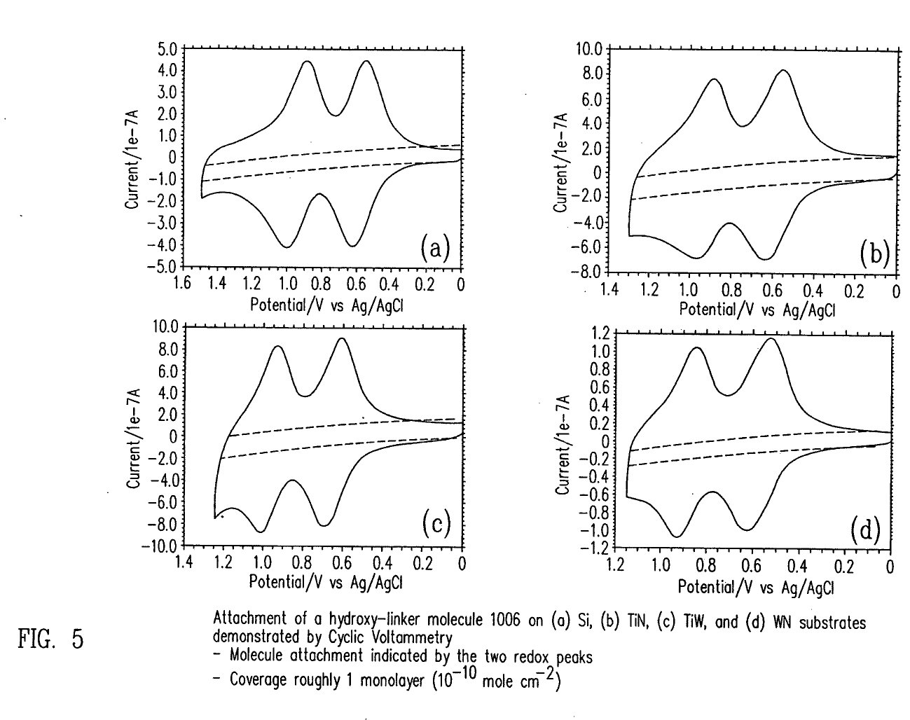

This example illustrates another exemplary approach to form a layer of organic molecules on semiconductor substrates (SS): (a) Si, (b) TiN, (c) TiW, and (d) WN. In this instance; a hydroxy-linker molecule 1006 is attached to semiconductor surface via the formation of C—O—SS bond. Commercial semiconductor wafer substrates were first cleaned by sonication for 5 minutes in acetone, water, and then isopropyl alcohol. The substrates were coated with a solution containing 1 mM of the porphyrin molecule in benzonitrile by spin-coating. The sample was then baked at 350° C. for 5 minutes and followed by solvent rinse to remove the residual unreacted molecules. As illustrated in FIG. 5, the attachment of a molecular layer on each substrate is demonstrated again by the porphyrin CV signature peaks.

### Example 3

### Molecule Attachment on Semiconductor Barrier Substrates

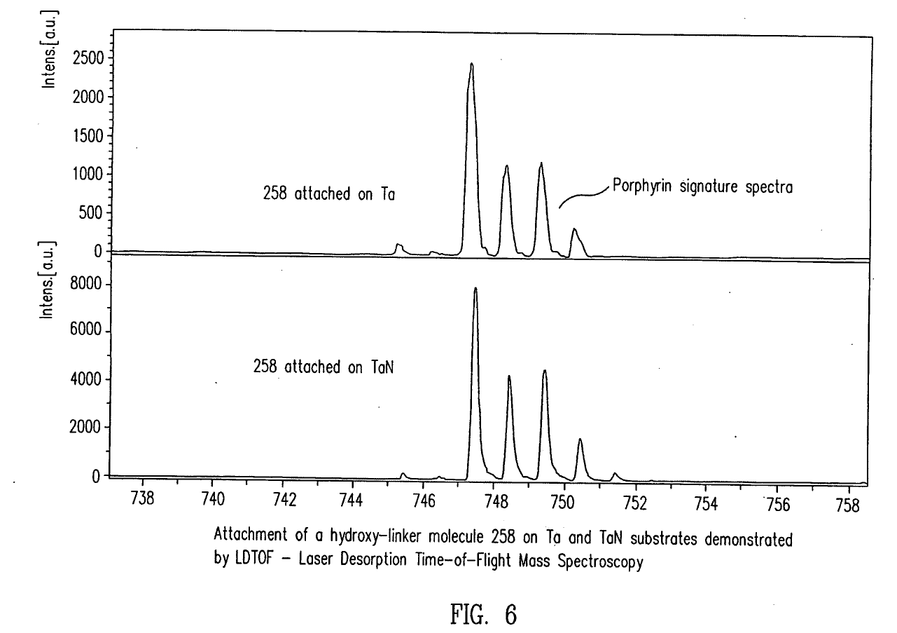

This example illustrates another exemplary approach to form a layer of organic molecules on semiconductor barrier substrates (BS) Ta and TaN. In this instance, a hydroxy-linker molecule 258 is attached to semiconductor surface via the formation of C—O—BM bond. Commercial barrier wafer substrates were first cleaned by sonication for 5 minutes in acetone, water, and then isopropyl alcohol. The substrates were coated with a solution, containing 1 mM of the porphyrin molecule in benzonitrile by spin-coating. The sample was then baked at 350° C. for 5 minutes and followed by solvent rinse to remove the residual unreacted molecules. In this case, the molecular layer formed can not be characterized by CV since the barrier substrates are electrically poorly conductive. The molecular layer was characterized by Laser Desorption Time-of-Flight Mass Spectroscopy (LDTOF) instead. FIG. 6 shows; exemplary LDTOF spectra that match the standard porphyrin signature spectra, suggesting the presence of attached porphyrin layer.

### Example 4

### Molecule Attachment on a PCB Epoxy Substrate

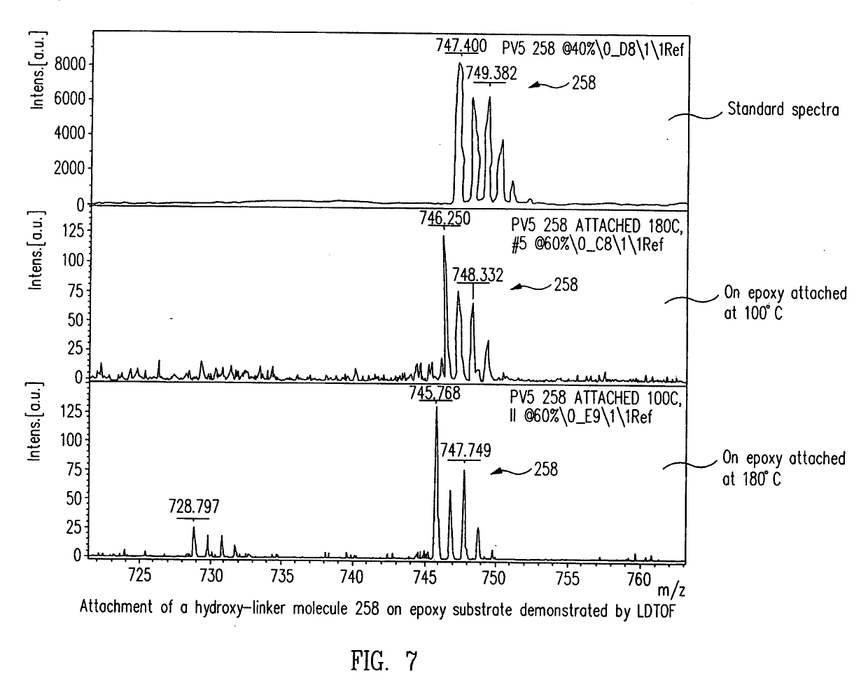

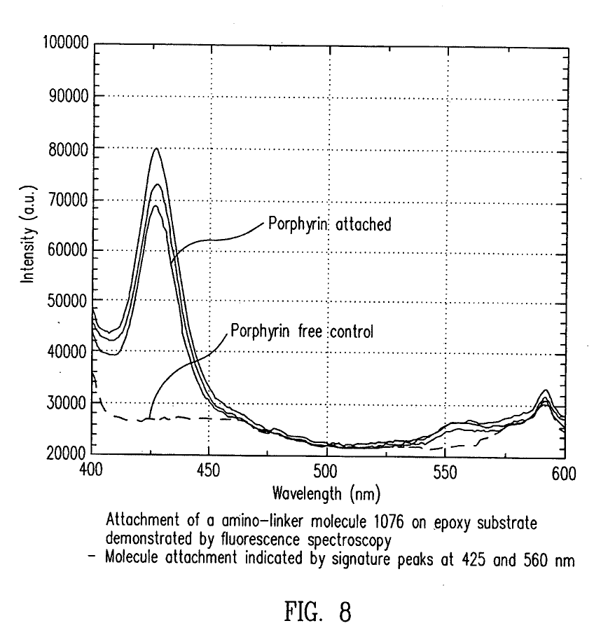

This example illustrates another exemplary approach to form a layer of organic molecules on a PCB substrate. In this instance, a hydroxy-linker molecule 258 and amino-linker molecule 1076 are attached to epoxy surface via the formation of C—O—C and C—N—C bonds, respectively. A commercial epoxy resin substrate was first cleaned by sonication for 5 minutes in water and then isopropyl alcohol. The substrate was coated with a solution containing 1 mM of the porphyrin molecule in toluene by dip-coating. The sample was then baked either at 100 or 180° C. for 20 minutes and followed by solvent rinse to remove the residual unattached molecules. The formation of molecular layer on the epoxy surface was identified by LDTOF, as shown in FIG. 7, and characterized more quantitatively by Fluorescence-Spectroscopy, as shown in FIG. 8.

### Example 5

### Demonstration of the Robustness of Molecule Layer on a Semiconductor Substrate

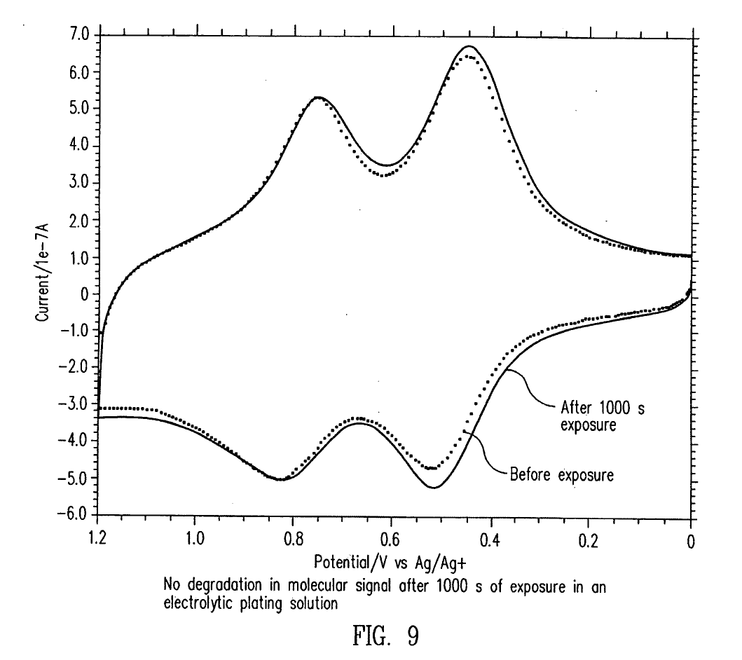

This example demonstrates the stability of molecular layer on a semiconductor substrate. Molecular layer formed oh a semiconductor substrate, as described in Example 2, was exposed to a variety of electrolytic plating solutions for a period of time up to 1000 seconds. The substrate was then reexamined by CV to determine the change of molecule coverage. As illustrated in FIG. 9, there is insignificant difference between CV signals recorded before and after the exposure, and therefore insignificant degradation in molecule coverage. This implies that the molecular layer formed on the semiconductor substrate is robust enough to survive the harsh chemical environment of electroplating.

### Example 6

### Demonstration of the Robustness of Molecule Layer on a PCB Epoxy Substrate

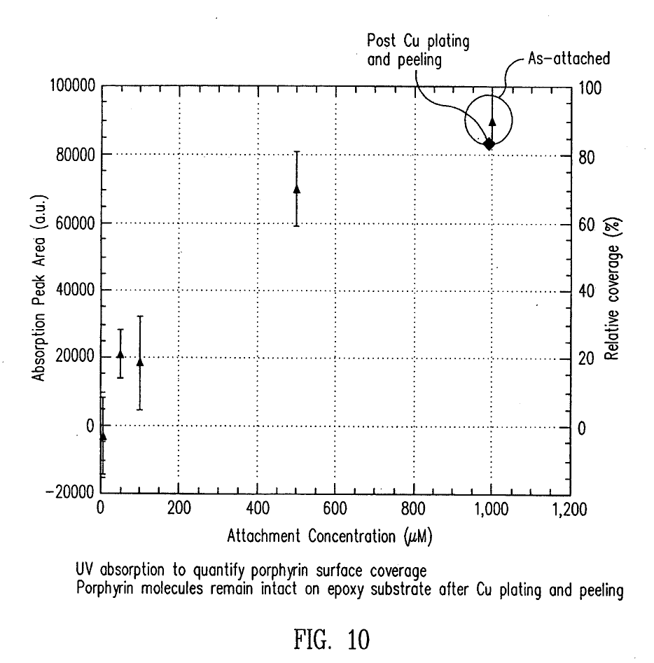

This example demonstrates the stability of molecular layer on a PCB expoxy substrate. Molecular layer formed on an epoxy substrate, as described in Example 4, was subjected to electroless Cu deposition process including (a) immersed in Shipley Circuposit Conditioner 3320 for 10 min at 65° C., (b) immersed in Cataposit Catalyst 404 at 23° C. for 1 min and then in Cataposit Catalyst 44 (Activation) at 40°G for 5 min, (c) immersed in Accelerator 19E at 30° C. for 5 min, (d) immersed in Cuposit 328L Copper Mix at 30° C. for 10 min. Following electroless deposition, the substrate was rinsed with water and dried, and the electroless Cu film was then removed to expose the epoxy substrate. The substrate was reexamined by Fluorescence Spectroscopy to determine the change of molecule coverage. As shown in FIG. 10, the molecule coverage, which is proportional to the UV absorption strength, increases with increase in attachment concentration. The exemplary molecular layer has a coverage corresponding to 1000 μM attachment concentration. As illustrated in FIG. 10, within experimental error, there is essentially no change in the molecule coverage post electroless plating process. This implies that the molecular layer formed oh the epoxy substrate is robust enough to survive the harsh chemical environment of electroless plating.

### Example 7

### Demonstration of the Enhancement of Copper Electroplating and Adhesion by Porphyrin Molecules Formed on a Semiconductor Substrate

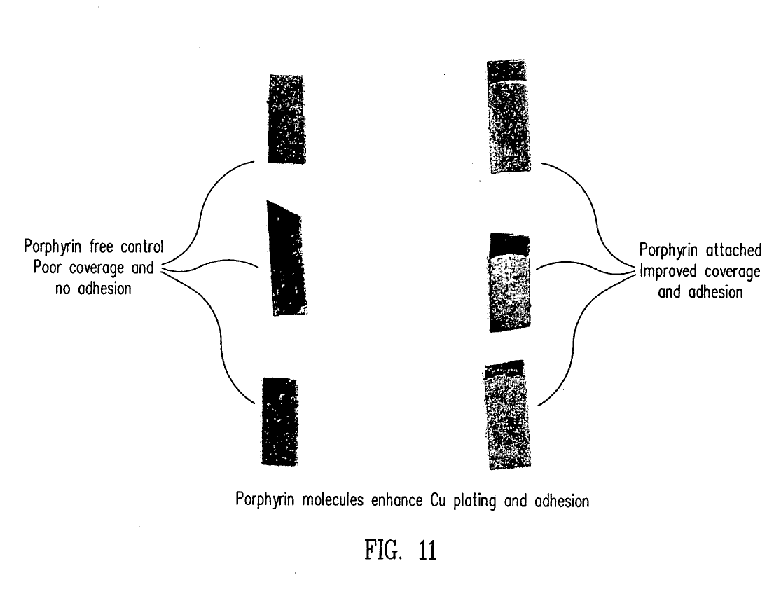

This example demonstrates the enhancement of copper electroplating and adhesion by porphyrin molecules formed on a semiconductor substrate. Molecular layer formed on a semiconductor substrate, as described in Example 2, was subjected to Cu electroplating in Shipley/Copper Gleam ST-901 Acid Copper at 1 A/dm², 23° C. for 100 min. FIG. 11 shows photographs of multiple, test coupons of electrolytic Cu layer formed on porphyrin attached substrates and porphyrin-free control substrates. As shown in FIG. 11, the molecule attached substrates show good Cu coverage and adhesion; in contrast the molecule-free control substrates show poor Cu coverage and practically no adhesion.

### Example 8

### Demonstration of the Enhancement of Copper Electroless Plating and Adhesion by Porphyrin Molecules Formed on a PCB Epoxy Substrate

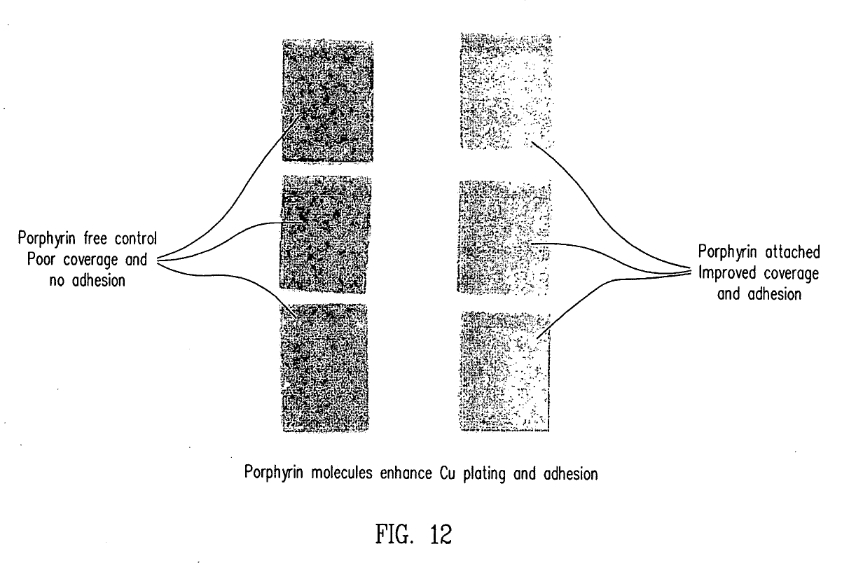

This example demonstrates the enhancement of copper electroless plating and adhesion by porphyrin molecules formed on a PCB epoxy substrate. Molecular layer formed on an epoxy substrate; as described in Example 4, was subjected to Cu electroless plating, as described in Example 6. FIG. 12 shows photographs of multiple test coupons of electroless. Cu layer formed on porphyrin attached substrates and porphyrin-free control substrates. As illustrated in FIG. 12, the molecule attached substrates show good Cu coverage and uniformity; in contrast the molecule-free control substrates show very small Cu coverage. Initial tape peeling evaluation of electroless Cu on the molecule attached substrate shows no peeling. The result suggests the porphyrin molecules of the present invention provide a good substrate for plating and enhance copper adhesion to the epoxy surface.

### Example 9

### Demonstration of the Enhancement of Epoxy Adhesion by Porphyrin Molecules Formed on a Cu Substrate

This example illustrates one exemplary approach to enhance the adhesion of epoxy on a Cu substrate. In this instance, a commercial electroplated Cu substrate was first cleaned with 1 M sodium hydroxide solution at 70° C. for 4 min, and then rinsed with water. The Cu substrate was further conditioned in 1 wt % hydrogen peroxide solution at RT for 1 min, and 3 wt % sulfuric acid solution at RT for 1 min, and then followed by water rinse and drying with hot air. The substrate was then coated with a solution containing 0.1 to 1 mM of the porphyrin molecule in an appropriate solvent (e.g., isopropyl alcohol, hexane, toluene, and the like) by dip-coating or spray coating. The sample was then dried at RT or baked at 50 to 200° C. for 20 minutes and followed by standard surface cleaning processes to remove the residual unattached molecules. The amount of molecule attached can be adjusted by varying the concentration of the molecule, the attachment temperature, and duration, and monitored by Cyclic Voltammetry (CV) shown in FIG. 4.

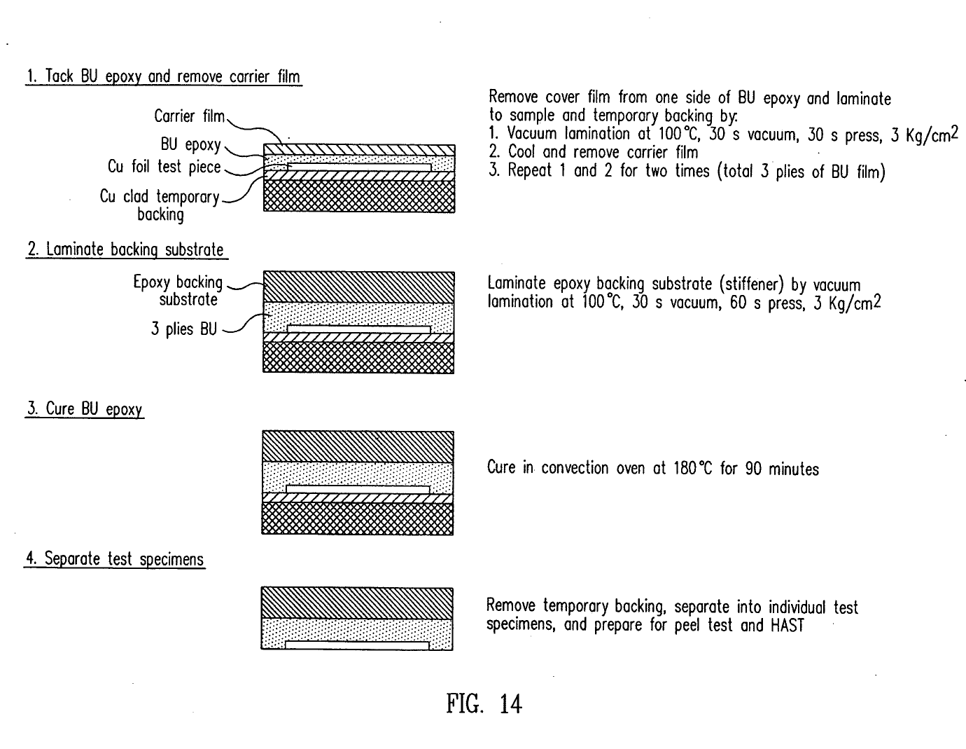

The molecule attached Cu test strips were laid out oh a temporary backing as illustrated in FIG. 13. A build-up (BU) epoxy (or dielectric) laminate film, which had been stabilized at ambient condition for at least 3 hours, was laid on top of the Cu strips as illustrated by step 1 of FIG. 14. The assembly was then vacuum laminated at 100° C., 30 s vacuum, and 30 s press at 3 Kg/cm². The lamination step was repeated twice to get total 3 plies of BU films.

To quantify the adhesion strength, a rigid backing substrate (stiffener) was laminated on top of the BU film as illustrated by step 2 of FIG. 14. The assembly was then heat treated or cured in a convection oven at 170-180° C. for 30 to 90 min.

Next the assembly was diced to remove temporary backing substrate and separate into individual test coupons for peel strength testing and highly accelerated stress test (HAST). The copper layer of the peel test coupon is clamped to the force gauge of a peel tester. Peel strength is then measured at a 90 degree peel angle and peel speed of 50 mm/min. Reliability testing was performed by preconditioning at 125° C. for 25 hours, then reflow three times at 260° C., followed by HAST at 30° C./60% RH at 96 hours. FIG. 15 illustrates the impact of molecule treatment on the peel strength retention post HAST. The smooth control without molecule treatment dropped 88% in peel strength post HAST, in contrast the molecule attached smooth substrate dropped 46% in peel strength, which is comparable or better than the roughened control which showed 51% loss. The tabular data of FIG. 15 also demonstrates that the enhancement in peel strength stability was achieved without significant change in surface roughness. Such results indicate that the molecular adhesion process and devices of the present invention significantly improve the ability to pattern copper lines at fine line spacing widths.

The foregoing methods, devices and description are intended to be illustrative. In view of the teachings provided herein, other approaches will be evident to those of skill in the relevant art, and such approaches are intended to fall within the scope of the present invention.

We claim:

1. A method of treating a surface to promote binding of one or more molecules of interest to the surface, comprising the steps of:
contacting at least one surface with one or more organic molecules comprising a thermally stable base bearing one or more binding groups configured to bind the molecules of interest and one or more attachment groups configured to attach to the organic molecule to at least one surface; and
attaching the organic molecules to the at least one surface by thermal, photochemical or electrochemical activation wherein the organic molecules form a monolayer on the surface, said monolayer exhibiting enhanced affinity for binding the molecules of interest.

2. The method of claim 1 wherein the monolayer of organic molecules is selectively formed on desired regions of the at least one surface, and the molecules of interest are formed atop said desired regions.

3. The method of claim 1 wherein the one or more organic molecules is a surface active moiety.

4. The method of claim 3 wherein said surface active moiety is selected from the group consisting of a macrocyclic proligand, a macrocyclic complex, a sandwich coordination complex and polymers thereof.

5. The method of claim 3 wherein said surface active moiety is a porphyrin.

6. The method of claim 1 wherein the one or more attachment group is comprised of an aryl functional group and/or an alkyl attachment group.

7. The method of claim 6 wherein the aryl functional group is comprised of a functional group selected from any one or more of: acetate, alkylamino, allyl, amine, amino, bromo, bromomethyl, carbonyl, carboxylate, carboxylic acid, dihydroxyphosphoryl, epoxide, ester, ether, ethynyl, formyl, hydroxy, hydroxymethyl, iodo, mercapto, mercaptomethyl, Se-acetylseleno, Se-acetylselenomethyl, S-acetylthio, S-acetylthiomethyl, selenyl, 4,4,5,5-tetramethyl-1,3,2-dioxaborolan-2-yl, 2-(trimethylsilyl)ethynyl, vinyl, and combinations thereof.

8. The method of claim 6 wherein the alkyl attachment group comprises a functional group selected from any one or more of: acetate, alkylamino, allyl, amine, amino, bromo, bromomethyl, carbonyl, carboxylate, carboxylic acid, dihydroxyphosphoryl, epoxide, ester, ether, ethynyl, formyl, hydroxy, hydroxymethyl, iodo, mercapto, mercaptomethyl, Se-acetylseleno, Se-acetylselenomethyl, S-acetylthio, S-acetylthiomethyl, selenyl, 4,4,5,5-tetramethyl-1,3,2-dioxaborolan-2-yl, 2-(trimethylsilyl)ethynyl, vinyl, and combinations thereof.

9. The method of claim 1 wherein the at least one attachment group is comprised of an alcohol or a phosphonate.

10. The method of claim 1 wherein the at least one attachment group is comprised of any one of more of: amines, alcohols, ethers, other nucleophile, phenyl ethynes, phenyl allylic groups, phosphonates and combinations thereof.

11. The method of claim 1 wherein the at least one substrate is comprised of any one of more of: electronic substrates, PCB substrates, semiconductor substrates, photovoltaic substrates, polymers, ceramics, carbon, epoxy, glass reinforced epoxy, phenol, polyimide resines, glass reinforced polyimide, cyanate, esters, Teflon, Group III-IV elements, plastics and mixtures thereof.

12. The method of claim 1 wherein the at least one substrate is comprised of any one of more of: a planar substrate, curved substrate, non-planar substrate, etched substrate, patterned or structured substrates, or deposited domain on another substrate.

13. The method of claim 1 wherein said contacting step comprises any one or more of: dipping, spraying, ink-jet printing, contact printing, vapor deposition, plasma assisted vapor deposition, sputtering, molecular beam epitaxy, and combinations thereof.

14. The method of claim 1 wherein thermal activation of the at least one substrate is carried out in any one or more of: an oven, hot plate, CVD device, furnace, rapid thermal heating furnace, MBE device, and combinations thereof.

15. The method of claim 1 wherein the one or more organic molecules and the at least one substrate are thermally activated by heating to a temperature of at least 25° C.

16. The method of claim 1 wherein the one or more organic molecules and the at least one substrate are thermally activated by heating to a temperature of at least 100° C.

17. The method of claim 1 wherein the one or more organic molecules and the at least one substrate are thermally activated by heating to a temperature of at least 150° C.

18. The method of claim 1 wherein the one or more organic molecules and the at least one substrate are thermally activated by heating to a temperature of up to about 400° C.

19. The method of claim 1 wherein the one or more organic molecules are carried in a solvent, dispersion, emulsion, paste, or gel.

20. The method of claim 1 further comprising:
applying a solvent rinse to the at least on surface prior to the contacting step.

21. The method of claim 1 further comprising:
cleaning the at least one surface of the substrate subsequent to the attaching step.

22. The method of claim 21 wherein said cleaning step comprises any one or more of: washing, rinsing, descuming or desmearing.

23. The method of claim 1 further comprising:
attaching the organic molecules to a second surface such that, the organic molecules form an interface between the at least one and second surfaces.

24. A coating or film, comprising:
one or more organic molecules, said organic molecules comprising a thermally stable base unit, one or more attachment groups configured to attach to a surface, and one or more binding groups,
wherein said one or more organic molecules provide a molecular adhesive.

25. The coating of claim 24 wherein the organic molecules form a sublayer on the surface which is functionalized with one or more elements.

26. The coating of claim 25 wherein the sublayer is functionalized by electro-deposition or electro-attaching of any one or more of: vinyl monomers, strained rings, diazonium salts; carboxylic acid salts, alkynes, Grignard derivatives, and combinations thereof.

27. The coating of claim 24 wherein said one or more binding groups are configured to bind to one or more biocompatible compounds to form a biocompatible coating.

28. The coating of claim 24 wherein said one or more binding groups are configured to bind to one of more hydrophilic compounds to form a hydrophilic coating.

29. The coating of claim 24 wherein said one or more binding groups are configured to bind to one or more corrosive resistant compounds to form a corrosive resistant coating.

30. The coating of claim 24 wherein said one or more binding groups are configured to bind to one or more hydrophobic compounds to form a hydrophobic coating.

31. The coating of claim 24 wherein said one or more binding groups are configured to bind to one or more compounds exhibiting optical absorption properties.

32. The coating of claim 24 wherein said one or more binding groups are configured to bind to one or more compounds exhibiting negative refractive index to form a stealth coating.

33. The coating of claim 24 wherein said attachment and binding groups are each configured to bind with a separate surface such that the coating is sandwiched between two substrates forming a structure.

34. The coating of claim 24 wherein said one or more binding groups are configured to bind to one or more semiconductor elements to form a semiconductive coating.

35. A method of forming a printed circuit board, comprising the steps of:
contacting a surface of a first PCB substrate with one or more organic molecules comprising a thermally stable base bearing one or more binding groups and one or more attachment groups configured to attach to the organic molecule to the surface of the first substrate;
heating the organic molecules and substrate to: a temperature of at least 25° C. wherein the organic molecules attach to the surface of the first substrate to form a monolayer on the surface;
placing the substrate in an electroless plating bath wherein metal ions in the plating bath are reduced and bind to the one or more binding groups carried on the organic molecules to form a metallic layer of the surface of the first substrate;
attaching a second layer of organic molecules on the metallic layer; and
attaching a second PCB substrate to said second layer of organic molecules by heating the organic molecules and substrate to a temperature of at least 25° C.

36. The method of claim 35 further comprising:
repeating the steps as desired to form a multilayered printed circuit board.

37. A kit for carrying out the binding molecules of interest to a substrate, comprising:
a container comprising a heat-resistant organic molecule derivatized with an attachment group Y and a binding group X, the binding group X promotes binding of the molecules of interest and attachment group Y promotes binding to the substrate; and
instructional materials teaching coupling the organic molecule to the substrate by heating the molecule and/or the surface to a temperature of at least 25° C.

38. A printed circuit board, comprising:
at least one metal layer;
a layer of organic molecules attached to the at least one metal layer; and
an epoxy layer atop said layer of organic molecules.

39. The printed circuit board of claim 38 wherein the layer of organic molecules is comprised of molecules having a thermally stable base bearing one or more binding groups configured to bind metals and one or more attachment groups configured to attach to the organic molecule to the substrate.

40. The printed circuit board of claim 38 wherein the layer of organic molecules is selected from the group of: a porphyrin, a porphyrinic macrocycle, an expanded porphyrin, a contracted porphyrin, a linear porphyrin polymer, a porphyrinic sandwich coordination complex, or a porphyrin array.

41. The printed circuit board of claim 38 further comprising at least two epoxy and metal layers forming a multi-layer printed circuit board.

42. The printed circuit board of claim 38 wherein said epoxy layer comprises one or more vias formed therethrough, said vias having a layer of organic molecules formed thereon and a metal layer atop said layer of organic molecules.

43. The printed circuit board of claim 38 wherein said layer of organic molecules forms a sublayer which is functionalized with one or more elements.

44. The printed circuit board of claim 43 wherein the sublayer is functionalized by electro-deposition or electro-attaching of any one or more of; vinyl monomers, strained rings, diazonium salts; carboxylic acid salts, alkynes, Grignard derivatives, and combinations thereof.

45. The coating of claim 33, where the structure is used as a liquid crystal display (LCD).

46. The coating of claim 33, where the structure is used as a flexible substrate.

47. The coating of claim 33, where the structure is used as plasma display.

48. The coating of claim 33, where the structure is used as a solar panel.

49. The printed circuit board of claim 38 wherein the metal layer exhibits a peel strength of greater than 0.5 kg/cm and a surface roughness of less than 250 nm.

50. The printed circuit board of claim 38 wherein the metal layer further comprises patterned metal lines formed thereon, said patterned metals lines having a width of equal to and less than 25 microns.

51. The printed circuit board of claim 38 wherein the metal layer further comprises patterned metal lines formed thereon, said patterned metals lines having a width of equal to and less than 15 microns.

52. The printed circuit board of claim 38 wherein the metal layer further comprises patterned metal lines formed thereon, said patterned metals lines having a width of equal to and less than 10 microns.

53. The printed circuit board of claim 38 wherein the metal layer further comprises patterned metal lines formed thereon, said patterned metals lines having a width of equal to and less than 5 microns.

54. A printed circuit board having one or more metal layers and one or more epoxy layers formed thereon, characterized in that: at least one of said one or more metal layers exhibits a peel strength of greater than 0.5 kg/cm and a surface roughness of less than 250 nm.

55. A printed circuit board having one or more metal layers and one or more epoxy layers, characterized in that: at least one of said one or more metal layers further comprises patterned metal lines formed thereon, said patterned metals lines having a width of 25 microns and less.
